(19) United States
(12) Patent Application Publication
(10) Pub. No.: US 2024/0162122 A1
(43) Pub. Date: May 16, 2024

(54) SEMICONDUCTOR DEVICE

(71) Applicant: SUMITOMO ELECTRIC INDUSTRIES, LTD., Osaka (JP)

(72) Inventor: Hiroshi EGUSA, Osaka (JP)

(73) Assignee: SUMITOMO ELECTRIC INDUSTRIES, LTD., Osaka (JP)

(21) Appl. No.: 18/282,556

(22) PCT Filed: Mar. 10, 2022
(86) PCT No.: PCT/JP2022/010645

§ 371 Date: Sep. 18, 2023

(30) Foreign Application Priority Data
Mar. 24, 2021 (JP) 2021-050411

(51) Int. Cl. H01L 23/495; H01L 23/00; H01L 23/36; H01L 23/538; H01L 25/07

(52) U.S. Cl. CPC H01L 23/49541; H01L 23/36; H01L 23/5383; H01L 24/48; H01L 25/072; H01L 2224/48175

(57) ABSTRACT

A semiconductor device includes a first conductor, a second conductor, a first transistor chip mounted on the first conductor, a second transistor chip mounted on the second conductor, a plate-shaped P terminal, a plate-shaped O terminal, and a plate-shaped N terminal. The P terminal is electrically connected to the first conductor. The O terminal is bonded to the second conductor. As viewed in a thickness direction of the first transistor chip, the O terminal includes a region overlapping with the first conductor with spacing therebetween in the thickness direction. The N terminal includes a region overlapping with the second conductor with spacing therebetween in the thickness direction.

### TECHNICAL FIELD

The present disclosure relates to a semiconductor device.

The present application claims priority based on Japanese Patent Application No. 2021-50411 filed on Mar. 24, 2021, the entire contents of which are incorporated herein by reference.

### BACKGROUND ART

A semiconductor device including a semiconductor element is known (see, for example, Patent Literature 1). The semiconductor device disclosed in Patent Literature 1 includes a heat spreader, a semiconductor element fixed to a mounting surface of the heat spreader with a bonding material, and a sealing resin covering the heat spreader and the semiconductor element.

### CITATION LIST

### Patent Literature

Patent Literature 1: Japanese Patent Application Laid-Open No. 2018-14357

### SUMMARY OF INVENTION

A semiconductor device according to the present disclosure includes a first conductor, a second conductor, a first transistor chip mounted on the first conductor, a second transistor chip mounted on the second conductor, a plate-shaped P terminal, a plate-shaped O terminal, and a plate-shaped N terminal. The first transistor chip has a source pad electrically connected to the O terminal. The second transistor chip has a source pad electrically connected to the N terminal. The first transistor chip has a drain pad electrically connected to the first conductor. The second transistor chip has a drain pad electrically connected to the second conductor. The P terminal is electrically connected to the first conductor. The O terminal is bonded to the second conductor. As viewed in a thickness direction of the first transistor chip, the O terminal includes a region overlapping with the first conductor with spacing therebetween in the thickness direction. The N terminal includes a region overlapping with the second conductor with spacing therebetween in the thickness direction.

### BRIEF DESCRIPTION OF DRAWINGS

FIG. 1 is a schematic perspective view of a semiconductor device in Embodiment 1.

FIG. 2 is a schematic perspective view of the semiconductor device shown in FIG. 1, with an illustration of a sealing material described below omitted.

FIG. 3 is a schematic plan view of the semiconductor device shown in FIG. 2.

FIG. 4 is a schematic perspective view of the semiconductor device shown in FIG. 2, with illustrations of a frame described below and also parts of P, O, and N terminals described below omitted.

FIG. 5 is a schematic plan view of the semiconductor device shown in FIG. 4.

FIG. 6 is a schematic side view of the semiconductor device as viewed in the direction indicated by the arrow VI in FIG. 5.

FIG. 7 is a schematic side view of the semiconductor device as viewed in the direction indicated by the arrow VII in FIG. 5.

FIG. 8 is a schematic perspective view of the semiconductor device shown in FIG. 4, with illustrations of the P, O, and N terminals, and also of wires, a first gate control terminal, a second gate control terminal, a first source sense control terminal, and a second source sense control terminal, described below, omitted.

FIG. 9 is a diagram schematically illustrating a portion of a circuit diagram of the semiconductor device shown in FIG. 1.

FIG. 10 is a schematic perspective diagram showing, in enlarged view, a portion of the semiconductor device in Embodiment 1.

FIG. 11 is a schematic perspective diagram showing, in enlarged view, a portion of the semiconductor device in Embodiment 1.

FIG. 12 is a schematic plan view of a current path between the P terminal and the O terminal.

FIG. 13 is a schematic plan view of a current path between the O terminal and the N terminal.

FIG. 14 is a schematic cross-sectional view of a portion of a semiconductor device that includes a diode chip.

FIG. 15 is a schematic cross-sectional view of a portion of a semiconductor device that includes a diode chip.

FIG. 16 is a schematic plan view of a semiconductor device in Embodiment 2.

FIG. 17 is a schematic perspective view of a semiconductor device in Embodiment 3, with illustrations of a sealing material, a frame, and the like omitted.

FIG. 18 is a schematic plan view of the semiconductor device shown in FIG. 17.

FIG. 19 is a schematic side view of the semiconductor device shown in FIG. 18, as viewed in the direction indicated by the arrow XIX in FIG. 18.

FIG. 20 is a schematic perspective view of a semiconductor device in Embodiment 4, with illustrations of a sealing material, a frame, and the like omitted.

FIG. 21 is a schematic plan view of the semiconductor device shown in FIG. 20.

FIG. 22 is a schematic side view of the semiconductor device shown in FIG. 21, as viewed in the direction indicated by the arrow XXII in FIG. 21.

### DESCRIPTION OF EMBODIMENTS

### Problems to be Solved by Present Disclosure

In the semiconductor device disclosed in Patent Literature 1, it is required to reduce inductance.

Therefore, one of the objects is to provide a semiconductor device in which inductance can be reduced.

### Advantageous Effects of Present Disclosure

The semiconductor device described above is capable of reducing inductance.

### DESCRIPTION OF EMBODIMENTS OF PRESENT DISCLOSURE

Embodiments of the present disclosure will be firstly listed and described. A semiconductor device according to the present disclosure includes a first conductor, a second conductor, a first transistor chip mounted on the first conductor, a second transistor chip mounted on the second conductor, a plate-shaped P terminal, a plate-shaped O terminal, and a plate-shaped N terminal. The first transistor chip has a source pad electrically connected to the O terminal. The second transistor chip has a source pad electrically connected to the N terminal. The first transistor chip has a drain pad electrically connected to the first conductor. The second transistor chip has a drain pad electrically connected to the second conductor. The P terminal is electrically connected to the first conductor. The O terminal is bonded to the second conductor. As viewed in a thickness direction of the first transistor chip, the O terminal includes a region overlapping with the first conductor with spacing therebetween in the thickness direction. The N terminal includes a region overlapping with the second conductor with spacing therebetween in the thickness direction.

For the semiconductor device disclosed in Patent Literature 1, wires are connected to the circuit pattern. In such a configuration, the heat spreaders need to be spaced apart from each other to prevent interference of the wire bonding tool, making it difficult to increase the heat dissipation area of the heat spreaders. Further, increasing the heat dissipation area of the heat spreaders also increases the length of the wires. This increases the wiring resistance, leading to increased inductance. Furthermore, if an attempt is made to reliably avoid the contact between the heat spreaders and the wires for the purpose of insulation, the wiring length of the wires will become even longer.

According to the above semiconductor device, as viewed in the thickness direction of the first transistor chip, the O terminal, which is bonded to the second conductor, includes a region overlapping with the first conductor with spacing therebetween in the thickness direction. The N terminal also includes a region overlapping with the second conductor with spacing therebetween in the thickness direction. Then, using the overlapping regions can reduce the length of the member connecting the O terminal to the first transistor chip. It can also reduce the length of the member connecting the N terminal to the second transistor chip. Accordingly, the path length of the current path can be shortened, leading to reduced inductance. Further, in the case where heat dissipation plates (heat spreaders) are used, the first transistor chip and the second transistor chip are mounted on the heat spreaders. This avoids entering of a wire bonding tool between the heat spreaders, so it becomes easy to increase the heat dissipation area of the heat spreaders, thereby improving heat dissipation properties.

In the above semiconductor device, the bonding between the O terminal and the second conductor may include at least one of ultrasonic bonding and bonding by welding. This ensures more reliable bonding between the O terminal and the second conductor.

Further, a semiconductor device according to the present disclosure includes a first conductor, a second conductor, a first transistor chip mounted on the first conductor, a second transistor chip mounted on the second conductor, a plate-shaped P terminal, a plate-shaped O terminal, and a plate-shaped N terminal. The first transistor chip has a source pad electrically connected to the O terminal. The second transistor chip has a source pad electrically connected to the N terminal. The first transistor chip has a drain pad electrically connected to the first conductor. The second transistor chip has a drain pad electrically connected to the second conductor. The P terminal is electrically connected to the first conductor. The O terminal is bonded to the second conductor with a bonding material having electrical conductivity. As viewed in a thickness direction of the first transistor chip, the O terminal includes a region overlapping with the first conductor with spacing therebetween in the thickness direction. The N terminal includes a region overlapping with the second conductor with spacing therebetween in the thickness direction.

According to the above semiconductor device, as viewed in the thickness direction of the first transistor chip, the O terminal, which is connected to the second conductor with the electrically conductive bonding material, includes a region overlapping with the first conductor with spacing therebetween in the thickness direction. The N terminal also includes a region overlapping with the second conductor with spacing therebetween in the thickness direction. Then, with the use of the overlapping regions, the length of the member connecting the O terminal to the first transistor chip can be reduced. The length of the member connecting the N terminal to the second transistor chip can also be reduced. Accordingly, the path length of the current path can be shortened, leading to reduced inductance. In the case where heat dissipation plates (heat spreaders) are used, the first and second transistor chips are mounted on the heat spreaders. This avoids entering of a wire bonding tool between the heat spreaders, so it becomes easy to increase the heat dissipation area of the heat spreaders, thereby improving heat dissipation properties.

In the above semiconductor device, the bonding between the O terminal and the second conductor may include at least one of bonding with solder, bonding with wire, and bonding with a sintering material. With this, an efficient connection using a bonding material can be made between the O terminal and the second conductor.

In the above semiconductor device, at least one of the first and second conductors may include a heat dissipation plate. This makes it possible to reduce the heat generated from the transistor chips by improving the heat dissipation properties with the heat dissipation plate, while reducing the inductance.

The above semiconductor device may further include a circuit substrate including a first circuit board and a second circuit board. The first conductor may include the first circuit board. The second conductor may include the second circuit board. In this manner, in the case of using a heat dissipation plate, a thicker heat dissipation plate can be arranged, leading to further improvement of heat dissipation properties.

The above semiconductor device may further include a first conductive member and a second conductive member. The source pad of the first transistor chip may be connected to the O terminal with the first conductive member. The source pad of the second transistor chip may be connected to the N terminal with the second conductive member. In this manner, the first and second conductive members can be used to provide a more reliable electrical connection. The first and second conductive members may include at least one of wires and copper clips. The copper clip may be integrated with the O terminal or the N terminal.

In the above semiconductor device, the electrical connection between the P terminal and the first conductor may include at least one of bonding with solder, ultrasonic bonding, bonding by welding, bonding with wire, and bonding by sintering. This makes it possible to realize an electrical connection between the P terminal and the first conductor that is more suited to the user requirements and the characteristics required as the semiconductor device.

In the above semiconductor device, the O terminal may include a region arranged parallel to the N terminal. According to this configuration, by making the direction of the current flowing through the O terminal and the direction of the current flowing through the N terminal opposite to each other in the regions arranged in parallel, the magnetic fluxes generated when the current flows through the terminals are canceled, and the inductance of the current path is subtracted by the mutual inductance. The inductance can thus be reduced. Here, parallel does not mean having a relationship of geometrically strictly parallel. For example, one may be inclined to the other by a plurality of degrees, specifically within a range of 30 degrees.

In the above semiconductor device, at least one of the P terminal and the first conductor may include a region arranged parallel to the O terminal. According to such a configuration, by making the direction of the current flowing through at least one of the P terminal and the first conductor and the direction of the current flowing through the O terminal opposite to each other in the regions arranged in parallel, the magnetic fluxes generated when the current flows through the terminals or the first conductor and the O terminal are canceled, and the inductance of the current path is subtracted by the mutual inductance. The inductance can thus be reduced.

In the above semiconductor device, at least one of the P terminal and the first conductor may include a region arranged parallel to the O terminal and the N terminal. With this, the inductance of the path from the P terminal to the N terminal can also be reduced.

The above semiconductor device may further include a diode chip electrically connected in parallel with at least one of the first transistor chip and the second transistor chip. This allows a return current to flow through the diode chip, thereby preventing an overvoltage from being applied to the first transistor chip and the second transistor chip. Accordingly, reliability can be improved.

In the above semiconductor device, the first transistor chip and the diode chip may be electrically connected in parallel. The diode chip may be arranged on the O terminal side with respect to the first transistor chip. This makes it possible to reduce the length of a connecting member that connects a gate pad of the first transistor chip to a gate control terminal. Thus, the wiring length can be shortened, leading to reduced inductance.

In the above semiconductor device, the first transistor chip and the diode chip may be electrically connected in parallel. The first transistor chip may be arranged on the O terminal side with respect to the diode chip. This makes it possible to reduce the length of a connecting member that connects the source pad of the first transistor chip to a source sense control terminal. Thus, the wiring length can be shortened, leading to reduced inductance.

In the above semiconductor device, a plurality of first transistor chips may be provided. A plurality of second transistor chips may be provided. In this manner, the number of chips can be increased in accordance with the current.

In the above semiconductor device, as viewed in the thickness direction of the first transistor chip, the O terminal may be connected to the first transistor chip in a region of the O terminal arranged parallel to the P terminal. The N terminal may be connected to the second transistor chip in a region of the N terminal arranged parallel to the O terminal. With this, variation in the loop inductance in each chip of the plurality of transistor chips connected in these regions can be suppressed because the inductance is reduced in the regions arranged in parallel.

In the above semiconductor device, a plurality of first conductive members may be provided. The plurality of first conductive members may each have an equivalent length. A plurality of second conductive members may be provided. The plurality of second conductive members may each having an equivalent length. In this manner, variation in the loop inductance in each chip can be suppressed. Here, equivalent does not mean completely identical. For example, equivalent in inductance means that the inductance of one is not less than 50% and not more than 150% of the inductance of the other. For example, if the inductance of one is 20 nH and the inductance of the other is not less than 10 nH and not more than 30 nH, then it can be said that they are equivalent in inductance. Further, equivalent in length means that it includes even the case that the length of one first conductive member is longer than the length of another first conductive member in the range of 10 mm to 50 mm.

The above semiconductor device may further include a plate-shaped gate control terminal connected to a gate pad of the first transistor chip or a gate pad of the second transistor chip. As viewed in the thickness direction of the first transistor chip, the gate control terminal may have a region overlapping with the first conductor or the second conductor with spacing therebetween in the thickness direction. This makes it possible to use the overlapping region to reduce the length of a member that connects the gate control terminal to the first or second conductor. Therefore, the path length of the current path can be shortened, leading to reduced inductance. In the case where heat dissipation plates (heat spreaders) are used, the first and second transistor chips are mounted on the heat spreaders. This avoids entering of a wire bonding tool between the heat spreaders, so it becomes easy to increase the heat dissipation area of the heat spreaders, thereby improving heat dissipation properties.

The above semiconductor device may further include a third conductive member. The gate control terminal may be electrically connected to the gate pad of the first transistor chip or the gate pad of the second transistor chip with the third conductive member. This makes it possible to use the third conductive member to provide a more reliable electrical connection. The third conductive member may include at least one of a wire or a copper clip. The copper clip may be integrated with the gate control terminal.

The above semiconductor device may further include a plate-shaped source sense control terminal connected to the source pad of the first transistor chip or the source pad of the second transistor chip. As viewed in the thickness direction of the first transistor chip, the source sense control terminal may have a region overlapping with the first conductor or the second conductor with spacing therebetween in the thickness direction. This makes it possible to use the overlapping region to reduce the length of a member that connects the source sense control terminal to the first or second conductor. Therefore, the path length of the current path can be shortened, leading to reduced inductance. When heat dissipation plates (heat spreaders) are used, the first and second transistor chips are mounted on the heat spreaders. This avoids entering of a wire bonding tool between the heat spreaders, so it becomes easy to increase the heat dissipation area of the heat spreaders, thereby improving heat dissipation properties.

The above semiconductor device may further include a fourth conductive member. The source sense control terminal may be electrically connected to the source pad of the first transistor chip or the source pad of the second transistor chip with the fourth conductive member. With this, the fourth conductive member can be used to provide a more reliable electrical connection. The fourth conductive member may include at least one of a wire and a copper clip. The copper clip may be integrated with the gate control terminal.

In the above semiconductor device, the gate control terminal may include a region arranged parallel to the source sense control terminal. This leads to reduced inductance as it is subtracted by the mutual inductance in the regions where the current flowing through the gate control terminal and the current flowing through the source sense control terminal are in opposite directions.

In the above semiconductor device, as viewed in the thickness direction of the first transistor chip, the gate control terminal may be connected to the first or second transistor chip in its region arranged parallel to the source sense control terminal. With this, variation in the gate loop inductance in each chip of the plurality of transistor chips connected in this region can be suppressed because the inductance is reduced in the regions arranged in parallel.

In the above semiconductor device, a plurality of third conductive members may be provided. The plurality of third conductive members may each have an equivalent length. A plurality of fourth conductive members may be provided. The plurality of fourth conductive members may each have an equivalent length. With this, variation in the gate loop inductance in each chip can be suppressed. Here, equivalent does not mean completely identical. For example, equivalent in inductance means that the inductance of one is not less than 50% and not more than 150% of the inductance of the other. For example, if the inductance of one is 20 nH and the inductance of the other is not less than 10 nH and not more than 30 nH, then it can be said that they are equivalent in inductance.

The above semiconductor device may further include a base plate for mounting the first conductor and the second conductor thereon, and a frame attached to the base plate to surround a space in which the first transistor chip and the second transistor chip are arranged. The frame may include a wall portion rising in a direction intersecting the base plate, and a rib extending from the wall portion to support at least one of the N terminal, the gate control terminal, and the source sense control terminal. In this manner, at least one of the N terminal, the gate control terminal, and the source sense control terminal can be supported by the rib included in the frame.

In the above semiconductor device, the rib may include a through hole penetrating in a thickness direction of the base plate. Providing the through hole in the rib in this manner makes it difficult for air bubbles, entrained in the resin during the injection of the sealing material, to remain in the lower region of the rib. Therefore, deterioration of the insulation performance of the sealing material can be suppressed, leading to improved reliability.

### Details of Embodiments of Present Disclosure

Embodiments of the semiconductor device of the present disclosure will be described below with reference to the drawings. In the drawings referenced below, the same or corresponding portions are denoted by the same reference numerals and the description thereof will not be repeated.

### Embodiment 1

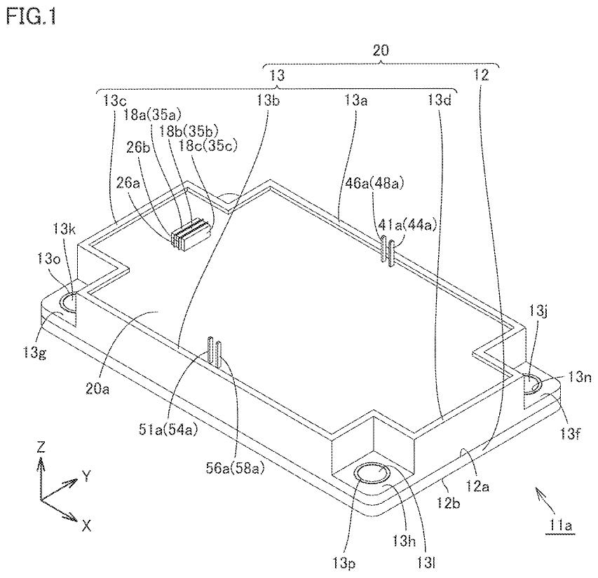

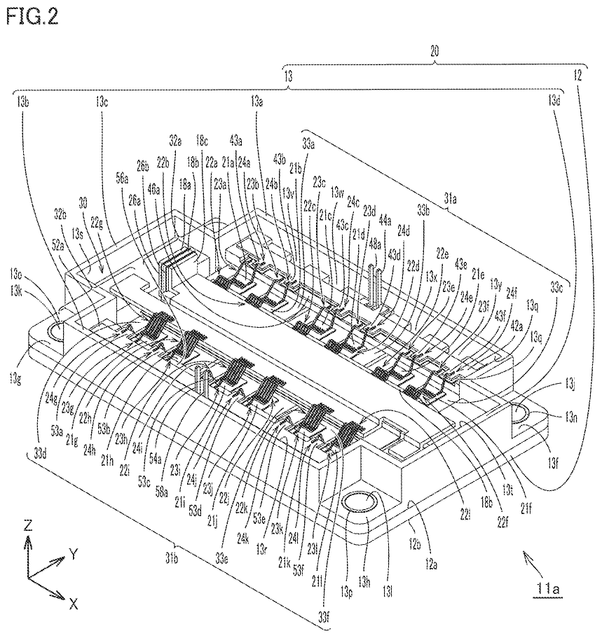

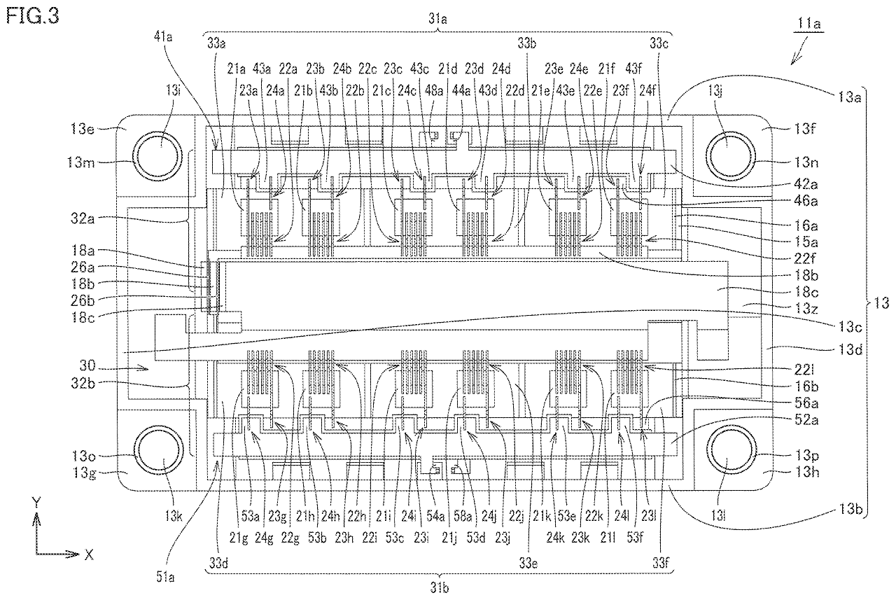

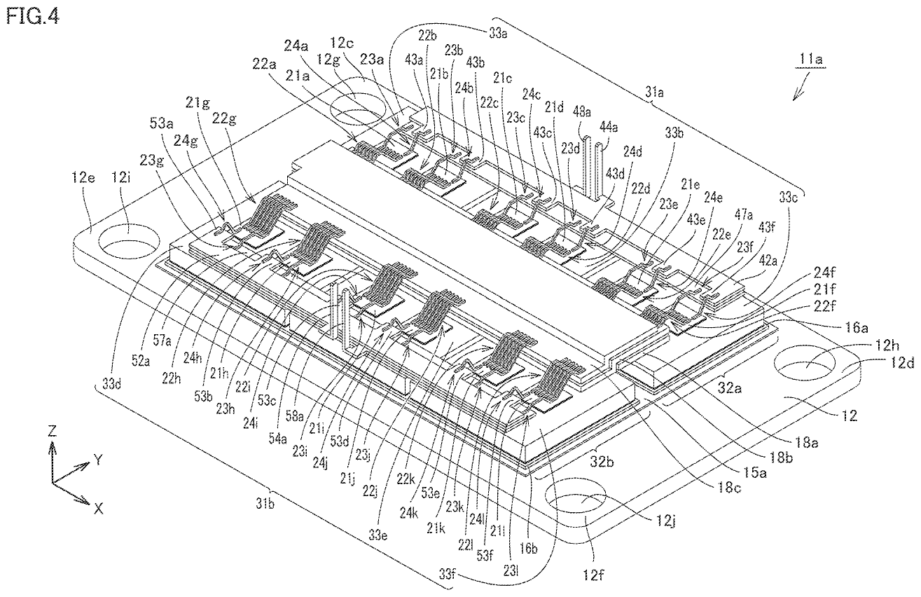

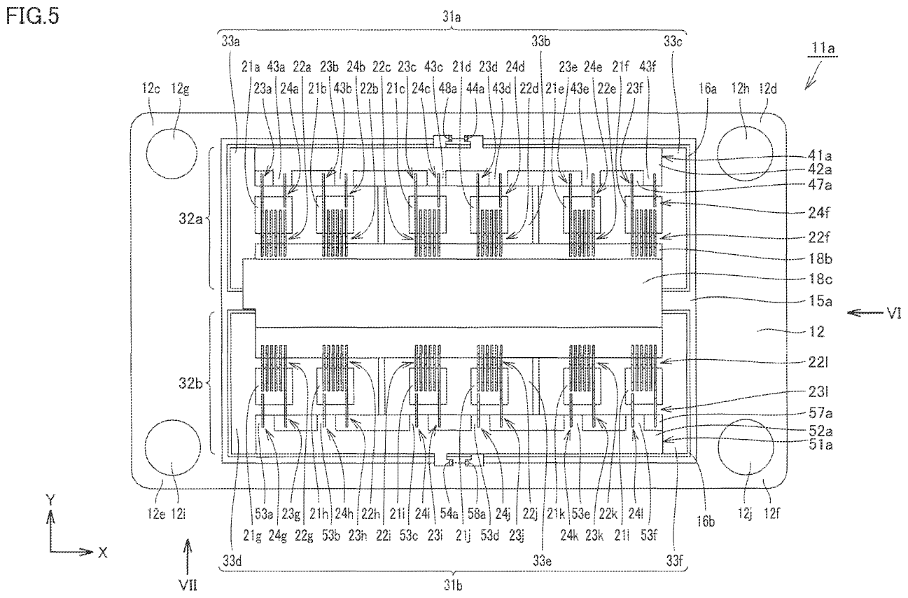

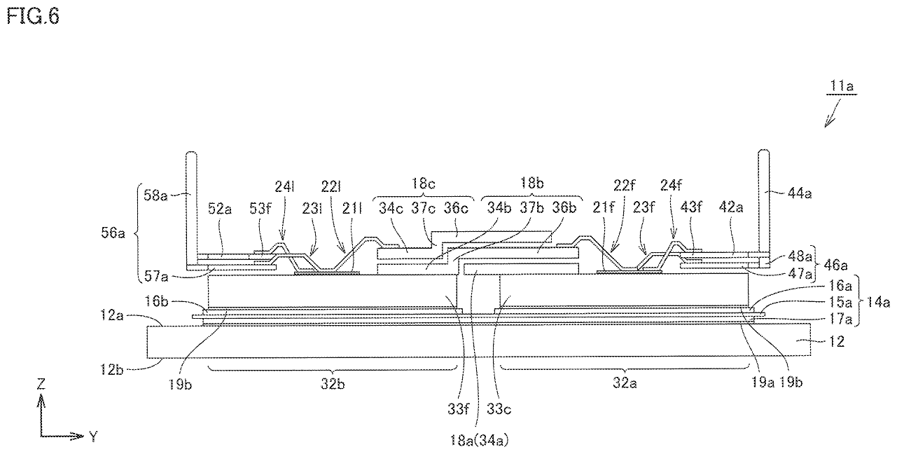

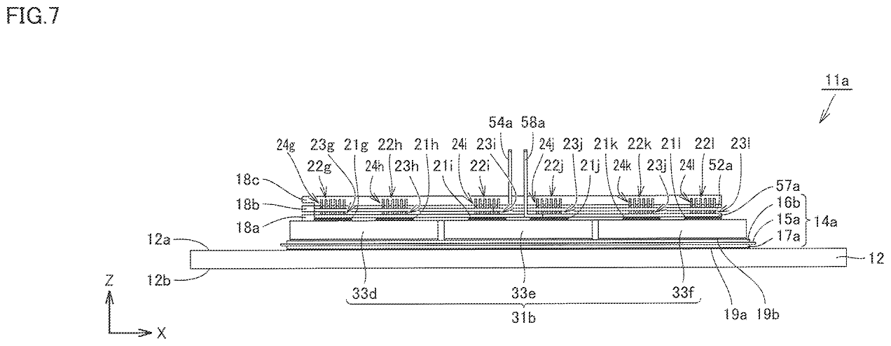

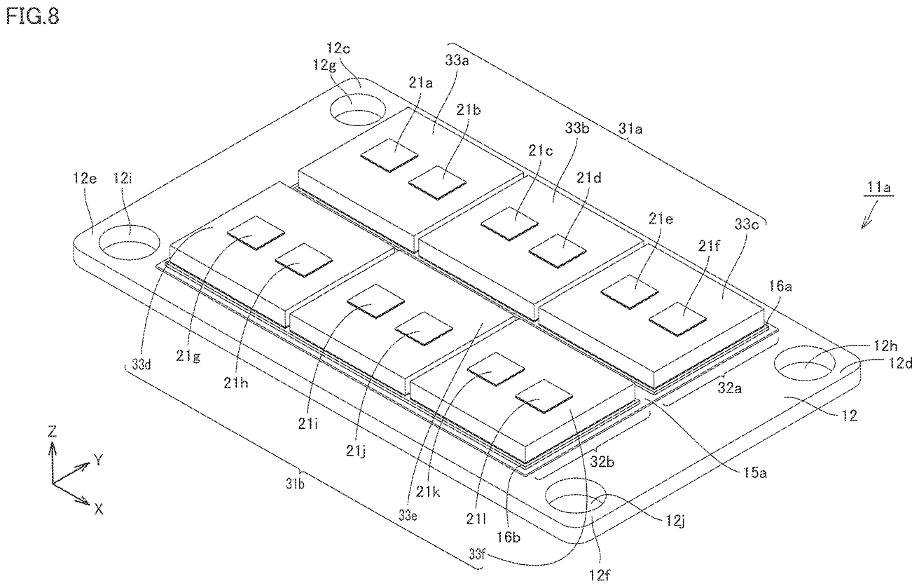

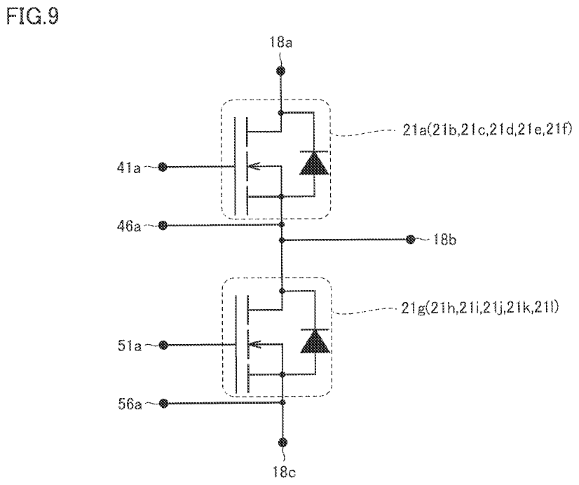

A description will be made of the configuration of a semiconductor device in Embodiment 1 of the present disclosure. FIG. 1 is a schematic perspective view of a semiconductor device in Embodiment 1. FIG. 2 is a schematic perspective view of the semiconductor device shown in FIG. 1, with an illustration of a sealing material described below omitted. FIG. 3 is a schematic plan view of the semiconductor device shown in FIG. 2. FIG. 4 is a schematic perspective view of the semiconductor device shown in FIG. 2, with illustrations of a frame described below and also parts of P, O, and N terminals described below omitted. FIG. 5 is a schematic plan view of the semiconductor device shown in FIG. 4. FIG. 6 is a schematic side view of the semiconductor device as viewed in the direction indicated by the arrow VI in FIG. 5. FIG. 7 is a schematic side view of the semiconductor device as viewed in the direction indicated by the arrow VII in FIG. 5. FIG. 8 is a schematic perspective view of the semiconductor device shown in FIG. 4, with illustrations of the P, O, and N terminals, and also of wires, a first gate control terminal, a second gate control terminal, a first source sense control terminal, and a second source sense control terminal, described below, omitted. FIG. 9 is a diagram schematically illustrating a portion of a circuit diagram of the semiconductor device shown in FIG. 1.

Referring to FIGS. 1 to 9, a semiconductor device 11a in Embodiment 1 includes a base plate 12, a frame 13 disposed on the base plate 12, a circuit substrate 14a disposed on the base plate 12, a P terminal 18a, an O terminal 18b, an N terminal 18c, a first gate control terminal (gate control terminal) 41a, a second gate control terminal (gate control terminal) 51a, a first source sense control terminal (source sense control terminal) 46a, a second source sense control terminal (source sense control terminal) 56a, first transistor chips 21a, 21b, 21c, 21d, 21e, and 21f, second transistor chips 21g, 21h, 21i, 21j, 21k, and 21l, three heat dissipation plates 33a, 33b, and 33c constituting a first conductor 31a, three heat dissipation plates 33d, 33e, and 33f constituting a second inductor 31b, wires 22a, 22b, 22c, 22d, 22e, and 22f serving as first conductive members, wires 22g, 22h, 22i, 22j, 22k, and 22l serving as second conductive members, wires 24a, 24b, 24c, 24d, 24e, 24f, 24g, 24h, 24i, 24j, 24k, and 24l serving as third conductive members, wires 23a, 23b, 23c, 23d, 23e, 23f, 23g, 23h, 23i, 23j, 23k, and 23l serving as fourth conductive members, and a sealing material 20a. The base plate 12 and the frame 13 constitute a case 20 provided for the semiconductor device 11a. The case 20 composed of the base plate 12 and the frame 13 has a space 30 therein, which space is filled with a resin as the sealing material 20a. For the type of the resin, epoxy resin, silicone gel, or urethane resin, for example, is selected. It should be noted that for the P terminal 18a, the O terminal 18b, and the N terminal 18c exposed from the sealing material 20a, a terminal block may be provided. Further, the semiconductor device 11a may be provided with a lid that is attached to the frame 13 to cover the sealing material 20a.

The base plate 12 is made of metal. The base plate 12 is made of copper, for example. The base plate 12 may have a surface plated with nickel or the like. The base plate 12 has a rectangular outer shape as viewed in its thickness direction, with the sides extending in the X direction as the long sides and the sides extending in the Y direction as the short sides, and with four rounded corners. The base plate 12 includes a first surface 12a located on one side in the thickness direction and a second surface 12b located on the other side in the thickness direction. On the second surface 12b of the base plate 12 located on the other side in the thickness direction, a heat dissipation fin (not shown) or the like for efficient heat dissipation, for example, may be attached. The thickness direction of the base plate 12 and the thickness direction of the circuit substrate 14a correspond to the Z direction. The base plate 12 has four corner regions 12c, 12d, 12e, and 12f provided with round through holes 12g, 12h, 12i, and 12j, respectively, passing straight therethrough in the Z direction.

The circuit substrate 14a is bonded onto the first surface 12a of the base plate 12 with a first bonding material 19a composed of, for example, solder. The circuit substrate 14a includes a first circuit board 16a and a second circuit board 16b having electrical conductivity, an insulating plate 15a having insulating properties, and a metal plate 17a. The first circuit board 16a and the second circuit board 16b are disposed on a surface on one side in the thickness direction of the insulating plate 15a, and the metal plate 17a is disposed on a surface on the other side in the thickness direction of the insulating plate 15a. In other words, the circuit substrate 14a is configured with the metal plate 17a, the insulating plate 15a, the first circuit board 16a, and the second circuit board 16b stacked together. As viewed in the thickness direction of the base plate 12, both the first circuit board 16a and the second circuit board 16b are rectangular in shape with the length in the X direction greater than the length in the Y direction. The first circuit board 16a and the second circuit board 16b are arranged spaced apart in the Y direction.

The frame 13 is attached to the base plate 12 so as to rise from the first surface 12a of the base plate 12 and surround the outer periphery of the circuit substrate 14a as viewed in the thickness direction of the base plate 12. The frame 13 is fixed to the first surface 12a of the base plate 12 by, for example, an adhesive not shown.

The frame 13 includes a first wall portion 13a including a first inner wall surface 13q, a second wall portion 13b including a second inner wall surface 13r, a third wall portion 13c including a third inner wall surface 13s, and a fourth wall portion 13d including a fourth inner wall surface 13t. The first wall portion 13a and the second wall portion 13b are arranged such that the first inner wall surface 13q and the second inner wall surface 13r face each other in the direction corresponding to the short side of the base plate 12 (Y direction) as viewed in the thickness direction of the base plate 12. The third wall portion 13c and the fourth wall portion 13d are arranged such that the third inner wall surface 13s and the fourth inner wall surface 13t face each other in the direction corresponding to the long side of the base plate 12 (X direction) as viewed in the thickness direction of the base plate 12. The first wall portion 13a, the second wall portion 13b, the third wall portion 13c, and the fourth wall portion 13d included in the frame 13 each rise in a direction intersecting the first surface 12a. Specifically, the first wall portion 13a, the second wall portion 13b, the third wall portion 13c, and the fourth wall portion 13d each rise perpendicular to the first surface 12a. The frame 13, as viewed in the thickness direction, has a rectangular outer shape, similar to the outer shape of the base plate 12, with the sides extending in the X direction as the long sides and the sides extending in the Y direction as the short sides, and with four rounded corners. The frame 13 has four corner regions 13e, 13f, 13g, and 13h provided with round through holes 13i, 13j, 13k, and 13l, respectively, passing straight therethrough in the Z direction. The frame 13 is attached to the base plate 12 such that the four through holes 13i, 13j, 13k, and 13l are arranged in the same positions as the four through holes 12g, 12h, 12i, and 12j of the base plate 12. The through holes 13i, 13j, 13k, and 13l have ring-shaped annular members 13m, 13n, 13o, and 13p, respectively, which are also called collars, made of metal, and press-fitted or insert molded into the holes.

With the exception of the annular members 13m, 13n, 13o, and 13p, a material with high insulating properties and high strength is used as the material of the frame 13. Specifically, polyphenylene sulfide (PPS) resin, for example, is adopted. Such resin is a thermoplastic resin having good moldability, excellent in insulating properties, moisture resistance, and thermal resistance, and also high in strength. It should be noted that polybutylene terephthalate (PBT) resin may also be used as the material of the frame 13.

The heat dissipation plates 33a, 33b, 33c, 33d, 33e, and 33f are each flat, and rectangular in shape as viewed in the thickness direction of the base plate 12. The heat dissipation plates 33a, 33b, 33c, 33d, 33e, and 33f are also called heat spreaders, and are composed of copperplate, for example. For the heat dissipation plates 33a, 33b, 33c, 33d, 33e, and 33f, the thickness (length in the Z direction) of 5 mm, for example, is selected. Alternatively, the thickness of 1.5 mm, 3 mm, 8 mm, or 10 mm may be selected for the heat dissipation plates 33a, 33b, 33c, 33d, 33e, and 33f. The heat dissipation plates 33a, 33b, 33c, 33d, 33e, and 33f are arranged spaced apart in the X and Y directions from each other. Specifically, the heat dissipation plates 33a and 33d are arranged to have the same position in the X direction and different positions in the Y direction. The heat dissipation plates 33b and 33e are arranged to have the same position in the X direction and different positions in the Y direction. The heat dissipation plates 33c and 33f are arranged to have the same position in the X direction and different positions in the Y direction. The heat dissipation plates 33a, 33b, and 33c are arranged in a row along the X direction. The heat dissipation plates 33d, 33e, and 33f are arranged in a row along the X direction. The heat dissipation plates 33a, 33b, and 33c are arranged on the first circuit board 16a. The heat dissipation plates 33a, 33b, and 33c are bonded to the first circuit board 16a with a second bonding material 19b composed of, for example, solder. The heat dissipation plates 33d, 33e, and 33f are arranged on the second circuit board 16b. The heat dissipation plates 33d, 33e, and 33f are bonded to the second circuit board 16b with the second bonding material 19b composed of, for example, solder.

The first transistor chips 21a, 21b, 21c, 21d, 21e, 21f and the second transistor chips 21g, 21h, 21i, 21j, 21k, 21l are wide bandgap semiconductor chips. Specifically, the first transistor chips 21a, 21b, 21c, 21d, 21e, 21f and the second transistor chips 21g, 21h, 21i, 21j, 21k, 21l each include a semiconductor layer composed of silicon carbide (SiC). It should be noted that the semiconductor layer may be composed of silicon (Si) or gallium nitride (GaN), for example.

The first transistor chips 21a, 21b, 21c, 21d, 21e, 21f and the second transistor chips 21g, 21h, 21i, 21j, 21k, 21l are metal-oxide-semiconductor field effect transistors (MOSFETs). In the present embodiment, the first transistor chips 21a, 21b, 21c, 21d, 21e, 21f and the second transistor chips 21g, 21h, 21i, 21j, 21k, 21l are vertical transistor chips. That is, the first transistor chips 21a, 21b, 21c, 21d, 21e, 21f and the second transistor chips 21g, 21h, 21i, 21j, 21k, 21l are transistor chips in which current flows in the thickness direction (Z direction). The first transistor chips 21a, 21b, 21c, 21d, 21e, 21f and the second transistor chips 21g. 21h, 21i, 21j, 21k, 21l are switching elements.

The first transistor chips 21a, 21b, 21c, 21d, 21e, and 21f are mounted on the heat dissipation plates 33a, 33b, and 33c. The first transistor chips 21a and 21b are arranged, spaced apart in the X direction, on the heat dissipation plate 33a. The first transistor chips 21a and 21b are bonded to the heat dissipation plate 33a with an electrically conductive bonding material not shown. The first transistor chips 21a and 21b have their drain pads electrically connected to the heat dissipation plate 33a. The first transistor chips 21c and 21d are arranged, spaced apart in the X direction, on the heat dissipation plate 33b. The first transistor chips 21c and 21d are bonded to the heat dissipation plate 33b with an electrically conductive bonding material not shown. The first transistor chips 21c and 21d have their drain pads electrically connected to the heat dissipation plate 33b. The first transistor chips 21e and 21f are arranged, spaced apart in the X direction, on the heat dissipation plate 33c. The first transistor chips 21e and 21f are bonded to the heat dissipation plate 33c with an electrically conductive bonding material not shown. The first transistor chips 21e and 21f have their drain pads electrically connected to the heat dissipation plate 33c. The second transistor chips 21g, 21h, 21i, 21j, 21k, and 21l are mounted on the heat dissipation plates 33d, 33e, and 33f. The second transistor chips 21g and 21h are arranged, spaced apart in the X direction, on the heat dissipation plate 33d. The second transistor chips 21g and 21h are bonded to the heat dissipation plate 33d with an electrically conductive bonding material not shown. The second transistor chips 21g and 21h have their drain pads electrically connected to the heat dissipation plate 33d. The second transistor chips 21i and 21j are arranged, spaced apart in the X direction, on the heat dissipation plate 33e. The second transistor chips 21i and 21j are bonded to the heat dissipation plate 33e with an electrically conductive bonding material not shown. The second transistor chips 21i and 21j have their drain pads electrically connected to the heat dissipation plate 33e. The second transistor chips 21k and 21l are arranged, spaced apart in the X direction, on the heat dissipation plate 33f. The second transistor chips 21k and 21l are bonded to the heat dissipation plate 33f with an electrically conductive bonding material not shown. The second transistor chips 21k and 21l have their drain pads electrically connected to the heat dissipation plate 33f.

The configuration of the P terminal 18a, the O terminal 18b, and the N terminal 18c will now be described. The P terminal 18a, the O terminal 18b, and the N terminal 18c each have a plate shape. The P terminal 18a, the O terminal 18b, and the N terminal 18c have electrical conductivity. In the present embodiment, the P terminal 18a, the O terminal 18b, and the N terminal 18c are each composed of a bent copper plate. The P terminal 18a, the O terminal 18b, and the N terminal 18c are arranged on the circuit substrate 14a. In the present embodiment, the P terminal 18a, the O terminal 18b, and the N terminal 18c are each disposed away from the first wall portion 13a, second wall portion 13b, third wall portion 13c, and fourth wall portion 13d constituting the frame 13.

The P terminal 18a includes a first flat region 34a parallel to the X-Y plane and a second flat region 35a parallel to the Y-Z plane. As viewed in the thickness direction (Z direction) of the base plate 12, the first flat region 34a is rectangular in shape with a length in the X direction longer than the length in the Y direction. The second flat region 35a is rectangular in shape as viewed in the X direction. For example, a piece of long copper plate can be bent at right angles to form the P terminal 18a including the first flat region 34a and the second flat region 35a. The first flat region 34a has a length in the X direction that is shorter than the length in the X direction of the heat dissipation plates 33a, 33b, and 33c bonded to the first circuit board 16a. The first flat region 34a of the P terminal 18a is bonded to each of the heat dissipation plates 33a, 33b, and 33c. That is, electrically conductive members are used to bond the first flat region 34a to the heat dissipation plates 33a, 33b, and 33c, whereby the P terminal 18a is electrically connected to the heat dissipation plates 33a, 33b, and 33c. It should be noted that the second flat region 35a is configured to have a portion exposed from the sealing material 20a. The second flat region 35a is located on the input/output side of the P terminal 18a.

The O terminal 18b includes a first flat region 34b and a third flat region 36b parallel to the X-Y plane, a second flat region 35b parallel to the Y-Z plane, and a fourth flat region 37b parallel to the X-Z plane. The first flat region 34b and the third flat region 36b are rectangular in shape with the length in the X direction longer than the length in the Y direction as viewed in the thickness direction (Z direction) of the base plate 12. The second flat region 35b is rectangular in shape as viewed in the X direction. The fourth flat region 37b is rectangular in shape as viewed in the Y direction. For example, a piece of copper plate can be punched and bent such that the outer shape of the copper plate achieves the final shape of the O terminal 18b, whereby the O terminal 18b including the first flat region 34b, the second flat region 35b, the third flat region 36b, and the fourth flat region 37b can be formed. The first flat region 34b has a length in the X direction that is shorter than the length in the X direction of the heat dissipation plates 33d, 33e, and 33f bonded to the second circuit board 16b. The first flat region 34b of the O terminal 18b is bonded to each of the heat dissipation plates 33d, 33e, and 33f. That is, electrically conductive members are used to bond the first flat region 34b to the heat dissipation plates 33d, 33e, and 33f, whereby the O terminal 18b is electrically connected to the heat dissipation plates 33d, 33e, and 33f. In the present embodiment, the O terminal 18b is bonded to the second conductor 31b. The O terminal 18b is arranged spaced apart from the P terminal 18a so as not to contact the P terminal 18a. The first flat region 34a of the P terminal and the third flat region 36b of the O terminal 18b have a parallel relationship. In other words, the first flat region 34a of the P terminal 18a and the third flat region 36b of the O terminal 18b constitute parallel plates. It should be noted that the second flat region 35b is configured to have a portion exposed from the sealing material 20a. The second flat region 35b is located on the input/output side of the O terminal 18b.

The N terminal 18c includes a first flat region 34c and a third flat region 36c parallel to the X-Y plane, a second flat region 35c parallel to the Y-Z plane, and a fourth flat region 37c parallel to the X-Z plane. The first flat region 34c and the third flat region 36c are rectangular in shape with the length in the X direction longer than the length in the Y direction as viewed in the thickness direction (Z direction) of the base plate 12. The second flat region 35c is rectangular in shape as viewed in the X direction. The fourth flat region 37c is rectangular in shape as viewed in the Y direction. For example, a piece of copper plate can be punched and bent such that the outer shape of the copper plate achieves the final shape of the N terminal 18c, whereby the N terminal 18c including the first flat region 34c, the second flat region 35c, the third flat region 36c, and the fourth flat region 37c can be formed. The first flat region 34c has a length in the X direction that is shorter than the length in the X direction of the heat dissipation plates 33d, 33e, and 33f bonded to the second circuit board 16b. The N terminal 18c is arranged spaced apart from the O terminal 18b so as not to contact the O terminal 18b. The first flat region 34b of the O terminal 18b and the first flat region 34b of the N terminal 18c have a parallel relationship. In other words, the first flat region 34b of the O terminal 18b and the first flat region 34c of the N terminal 18c constitute parallel plates. Further, the third flat region 36b of the O terminal 18b and the third flat region 36c of the N terminal 18c have a parallel relationship. In other words, the third flat region 36b of the O terminal 18b and the third flat region 36c of the N terminal 18c constitute parallel plates. It should be noted that the second flat region 35c is configured to have a portion exposed from the sealing material 20a. The second flat region 35c is located on the input/output side of the N terminal 18c.

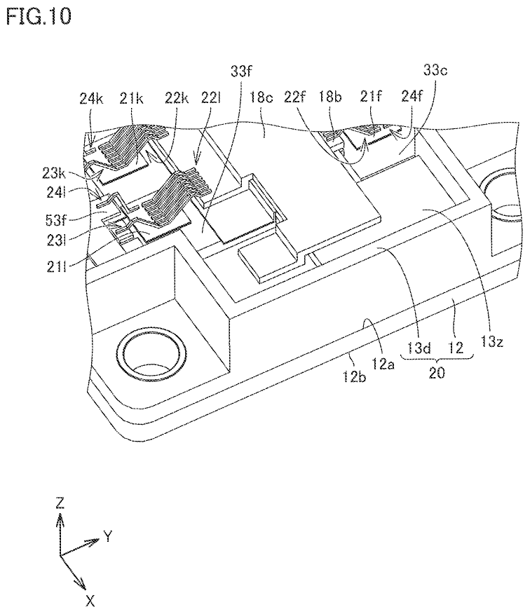

Here, the N terminal 18c is not bonded to any of the heat dissipation plates 33a, 33b, 33c, 33d, 33e, and 33f. The N terminal 18c is arranged to be supported by a rib 13z provided on the frame 13, as shown in FIG. 10. FIG. 10 is a schematic perspective diagram showing, in enlarged view, a portion of the semiconductor device 11a in Embodiment 1. Referring to FIG. 10, the frame 13 included in the semiconductor device 11a includes the rib 13z which supports the N terminal 18c. The rib 13z is provided on the fourth wall portion 13d and on the opposing third wall portion 13c included in the frame 13. The N terminal 18c may be attached to the frame 13 by having the N terminal 18c placed on and supported by the rib 13z.

It should be noted that the N terminal 18c may be attached to the frame 13 in the following manner. For example, the N terminal 18c may be fixed to the frame 13 with an adhesive, or the frame 13 may be provided with a resin pin extending in the Z direction and the N terminal 18c may have a portion provided with a through hole penetrating in the thickness direction, and the pin may be inserted into the through hole for attachment. Of course, it may be further secured with an adhesive. Alternatively, the frame 13 may be provided with a hole, and a nut may be placed in the hole. Then, with a bolt prepared, a through hole may be drilled in the N terminal 18c, and the bolt may be fixed by passing the body of the bolt through the through hole and tightening the bolt to the nut. Still alternatively, the frame 13 may be provided with an engagement portion to be engaged with the N terminal 18c, and the attachment may be done using an engagement by way of snap-fit or the like. The same applies to the attachment of the first gate control terminal 41a, the first source sense control terminal 46a, the second gate control terminal 51a, and the second source sense control terminal 56a to the frame 13.

The first gate control terminal 41a includes a first flat region 42a parallel to the X-Y plane, six protrusions 43a, 43b, 43c, 43d, 43e, and 43f spaced apart in the X direction and extending in the Y direction from the first flat region 42a, and a pin 44a extending in the Z direction. The pin 44a is configured to have a portion exposed from the sealing material 20a.

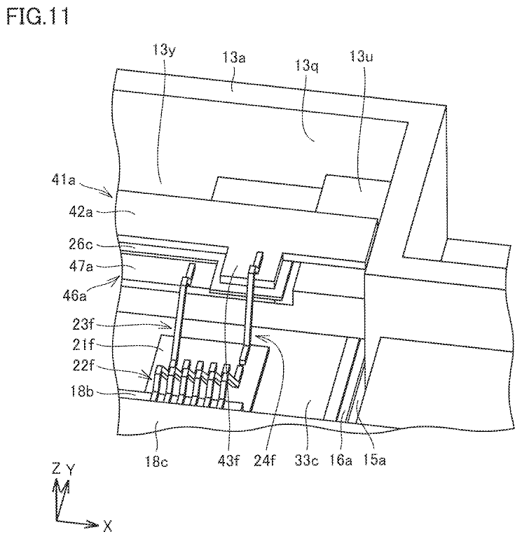

As shown in FIG. 11, the first gate control terminal 41a is arranged to be supported by a rib 13u provided in the frame 13. FIG. 11 is a schematic perspective diagram showing, in enlarged view, a portion of the semiconductor device 11a in Embedment 1. Here, the rib 13u is arranged to extend from the first wall portion 13a toward the second wall portion 13b of the frame 13. The rib 13u has through holes 13v, 13w, 13x, and 13y formed to penetrate in the thickness direction (Z direction) on the first inner wall surface 13q side of the first wall portion 13a. The plurality of through holes 13v, 13w, 13x, and 13y are formed spaced apart in the X direction. With the provision of such through holes 13v, 13w, 13x, and 13y, during the process of removing the air bubbles entrained in the resin upon injection of the sealing material 20a before curing, the bubbles can be made to move to the upper side of the rib 13u through the through holes 13v, 13w, 13x, and 13y. This prevents the entrained air from staying in the lower region of the rib 13u, making it easier to remove the air bubbles from within the sealing material 20a. Accordingly, the risk of air bubbles remaining in the sealing material 20a can be greatly reduced.

In particular, as a way of securing a wide area of the heat dissipation plates 33a, 33b, 33c, 33d, 33e, and 33f as viewed in the thickness direction of the base plate 12 for the purpose of improving the heat dissipation performance by the heat dissipation plates 33a, 33b, 33c, 33d, 33e, and 33f, it is conceivable to enlarge the heat dissipation plates 33a, 33b, 33c, 33d, 33e, and 33f to have them reach the lower region of the rib 13u. At this time, the spacing between the rib 13u and the heat dissipation plates 33a, 33b, 33c, 33d, 33e, and 33f, specifically the spacing in the Y direction, becomes narrower, in which case the air bubbles would likely remain in the lower region of the rib 13u. Providing the through holes 13v, 13w, 13x, and 13y can greatly reduce the risk of residual air bubbles even when the heat dissipation plates 33a, 33b, 33c, 33d, 33e, and 33f are increased in area.

The first source sense control terminal 46a includes a first flat region 47a parallel to the X-Y plane and a pin 48a extending in the Z direction. The first flat region 47a is arranged to be parallel to the first flat region 42a. In other words, the first flat region 42a of the first gate control terminal 41a and the first flat region 47a of the first source sense control terminal 46a constitute parallel plates. The pin 48a is configured to have a portion exposed from the sealing material 20a.

The second gate control terminal 51a includes a first flat region 52a parallel to the X-Y plane, six protrusions 53a, 53b, 53c, 53d, 53e, and 53f spaced apart in the X direction and extending in the Y direction from the first flat region 52a, and a pin 54a extending in the Z direction. The pin 54a is configured to have a portion exposed from the sealing material 20a.

The second source sense control terminal 56a includes a first flat region 57a parallel to the X-Y plane and a pin 58a extending in the Z direction. The first flat region 57a is arranged to be parallel to the first flat region 52a. In other words, the first flat region 52a of the second gate control terminal 51a and the first flat region 57a of the second source sense control terminal 56a constitute parallel plates. The pin 58a is configured to have a portion exposed from the sealing material 20a.

The first transistor chips 21a, 21b, 21c, 21d, 21e, and 21f have their source pads electrically connected to the O terminal 18b with the wires 22a, 22b, 22c, 22d, 22e, and 22f, which are the first conductive members, respectively. The first gate control terminal 41a is connected to the gate pads of the first transistor chips 21a, 21b, 21c, 21d, 21e, and 21f with the wires 24a, 24b, 24c, 24d, 24e, and 24f, which are the third conductive members, respectively. In this case, the wires 24a, 24b, 24c, 24d, 24e, and 24f are connected to the six protrusions 43a, 43b, 43c, 43d, 43e, and 43f included in the first gate control terminal 41a. The first source sense control terminal 46a is connected to the source pads of the first transistor chips 21a, 21b, 21c, 21d, 21e, and 21f with the wires 23a, 23b, 23c, 23d, 23e, and 23f, which are the fourth conductive members, respectively. The current path including the first transistor chips 21a, 21b, 21c, 21d, 21e, and 21f constitutes an upper arm 32a, which is a first arm.

The second transistor chips 21g, 21h, 21i, 21j, 21k, and 21l have their source pads electrically connected to the N terminal 18c with the wires 22g, 22h, 22i, 22j, 22k, and 22l, which are the first conductive members, respectively. The second gate control terminal 51a is connected to the gate pads of the second transistor chips 21g, 21h, 21i, 21j, 21k, and 21l with the wires 24g, 24h, 24i, 24j, 24k, and 24l, which are the third conductive members, respectively. In this case, the wires 24g, 24h, 24i, 24j, 24k, and 24l are connected to the six protrusions 53a, 53b, 53c, 53d, 53e, and 53f included in the second gate control terminal 51a. The second source sense control terminal 56a is connected to the source pads of the second transistor chips 21g, 21h, 21i, 21j, 21k, and 21l with the wires 23g, 23h, 23i, 23j, 23k, and 23l, which are the fourth conductive members, respectively. The current path including the second transistor chips 21g, 21h, 21i, 21j, 21k, and 21l constitutes a lower arm 32b, which is a second arm.

A method of producing the semiconductor device 11a having the above-described configuration will now be described in brief. First, the base plate 12 is prepared, and on the first surface 12a of the base plate 12, the circuit substrate 14a, the heat dissipation plates 33a, 33b, 33c, 33d, 33e, 33f, the first transistor chips 21a, 21b, 21c, 21d, 21e, 21f, the second transistor chips 21g, 21h, 21i, 21j, 21k, 21l, the P terminal 18a, and the O terminal 18b are bonded by reflow soldering. Next, the frame 13 is placed on and adhered to the first surface 12a of the base plate 12. Thereafter, the N terminal 18c, the first gate control terminal 41a, the first source sense control terminal 46a, the second gate control terminal 51a, and the second source sense control terminal 56a are disposed. It should be noted that insulating members 26a and 26b, composed of insulating paper or molded members of resin, are placed between respective two of the P, O, and N terminals 18a, 18b, and 18c. An insulating member 26c is also placed between the first gate control terminal 41a and the first source sense control terminal 46a and between the second gate control terminal 51a and the second source sense control terminal 56a. Thereafter, the wire 22a and others are attached by wiring to electrically connect the components. Lastly, the sealing material 20a is poured into the space 30 of the frame 13 and cured for sealing. In this manner, the semiconductor device 11a is produced. It should be noted that the P terminal 18a and the heat dissipation plates 33a, 33b, and 33c, and the O terminal 18b and the heat dissipation plates 33d, 33e, and 33f, may be bonded by welding in advance.

The above-described production method requires only one reflow soldering process, so the number of production processes can be reduced as compared to the case where wires are connected to the circuit pattern and then terminals are bonded by reflow soldering.

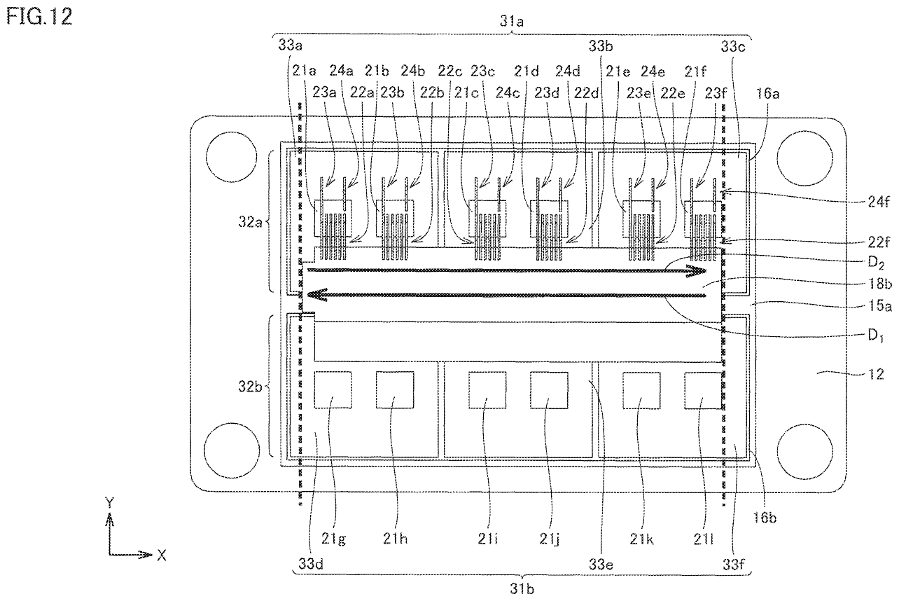

A description will now be made of the path of current flowing during the operation of the semiconductor device 11a. FIG. 12 is a schematic plan view of the current path between the P terminal 18a and the O terminal 18b. In FIG. 12, illustrations of some components are omitted. The region sandwiched between the bold broken lines is the region where the P terminal 18a and the O terminal 18b constitute the parallel plates. Referring to FIG. 12, the current path when current flows from the P terminal 18a to the O terminal 18b in the semiconductor device 11a is from the P terminal 18a to the heat dissipation plates 33a, 33b, 33c as the first conductor 31a, to the first transistor chips 21a, 21b, 21c, 21d, 21e, 21f, to the wires 22a, 22b, 22c, 22d, 22e, 22f, and to the O terminal 18b. Here, in the P terminal 18a, current flows in the direction indicated by the arrow D₁. On the other hand, in the O terminal 18b, current flows in the direction indicated by the arrow D₂. That is, the direction of the current flowing through the P terminal 18a and the direction of the current flowing through the O terminal 18b are opposite to each other.

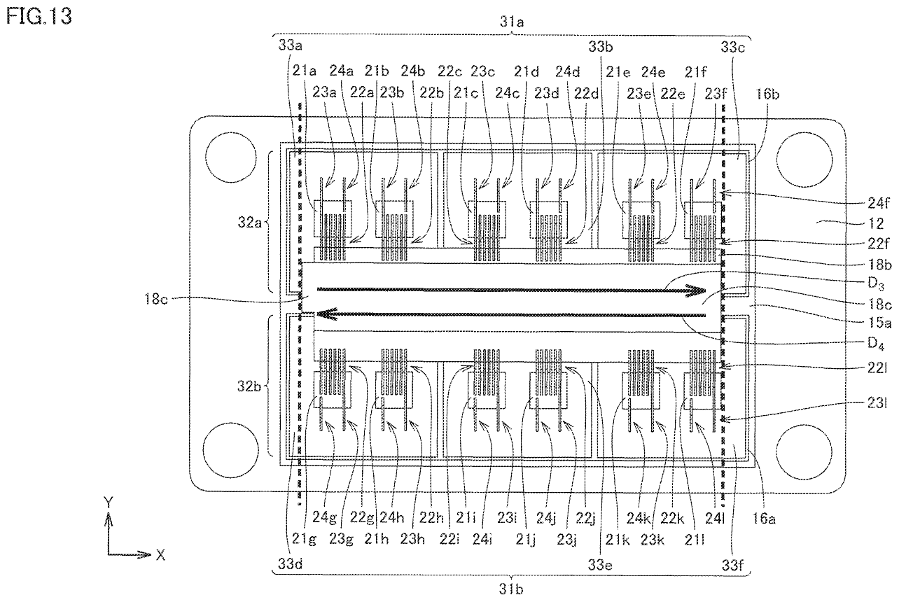

FIG. 13 is a schematic plan view of the current path between the O terminal 18b and the N terminal 18c. In FIG. 13, illustrations of some components are omitted. The region sandwiched between the bold broken lines is the region where the O terminal 18b and the N terminal 18c constitute the parallel plates. Referring to FIG. 13, the current path when current flows from the O terminal 18b to the N terminal 18c in the semiconductor device 11a is from the O terminal 18b to the heat dissipation plates 33d, 33e, 33f as the second conductor 31b, to the second transistor chips 21g, 21h, 21i, 21j, 21k, 21l, to the wires 22g, 22h, 22i, 22j, 22k, 22l, and to the N terminal 18c. Here, in the O terminal 18b, current flows in the direction indicated by the arrow D₃. On the other hand, in the N terminal 18c, current flows in the direction indicated by the arrow D₄. That is, the direction of the current flowing through the O terminal 18b and the direction of the current flowing through the N terminal 18c are opposite to each other.

In the semiconductor device 11a of the present disclosure, as viewed in the thickness direction of the first transistor chips, the O terminal 18b includes a region overlapping with the heat dissipation plates 33a, 33b, and 33c as the first conductor 31a, with spacing therebetween in the thickness direction. The N terminal 18c includes a region overlapping with the heat dissipation plates 33d, 33e, and 33f as the second conductor 31b, with spacing therebetween in the thickness direction. Then, with the use of the overlapping regions, the lengths of the conductive members connecting the O terminal 18b to the first transistor chips 21a, 21b, 21c, 21d, 21e, and 21f can be reduced. The lengths of the conductive members connecting the N terminal 18c to the second transistor chips 21g, 21h, 21i, 21j, 21k, and 21l can also be reduced. Accordingly, the path length of the current path can be shortened, leading to reduced inductance. In the present embodiment, the heat dissipation plates 33a, 33b, 33c, 33d, 33e, and 33f are used, and the first transistor chips 21a, 21b, 21c, 21d, 21e, and 21f and the second transistor chips 21g, 21h, 21i, 21j, 21k, and 21l are mounted on the heat dissipation plates 33a, 33b, 33c, 33d, 33e, and 33f. This avoids entering of a wire bonding tool between the heat dissipation plates 33a, 33b, 33c, 33d, 33e, and 33f, so it becomes easy to increase the heat dissipation area of the heat dissipation plates 33a, 33b, 33c, 33d, 33e, and 33f, thereby improving heat dissipation properties.

In the present embodiment, the bonding between the O terminal 18b and the second conductor 31b may include at least one of ultrasonic bonding and bonding by welding. This ensures more reliable bonding between the O terminal 18b and the second conductor 31b.

It should be noted that in the above embodiment, the O terminal 18b may be connected to the second conductor 31b with a bonding material having electrical conductivity. With this as well, the inductance can be reduced. The bonding between the O terminal 18b and the second conductor 31b may include at least one of bonding with solder, bonding with wire, and bonding with a sintering material. With this, an efficient connection using a bonding material can be made between the O terminal 18b and the second conductor 31b.

In the present embodiment, the first conductor 31a and the second conductor 31b include the heat dissipation plates 33a, 33b, 33c, 33d, 33e, and 33f. This makes it possible to improve the heat dissipation properties with the heat dissipation plates 33a, 33b, 33c, 33d, 33e, and 33f to thereby reduce the heat generated from the first transistor chips 21a, 21b, 21c, 21d, 21e, 21f and the second transistor chips 21g, 21h, 21i, 21j, 21k, 21l.

In the present embodiment, the source pads of the first transistor chips 21a, 21b, 21c, 21d, 21e, and 21f are connected to the O terminal 18b with the wires 22a, 22b, 22c, 22d, 22e, and 22f as the first conductive members. The source pads of the second transistor chips 21g, 21h, 21i, 21j, 21k, and 21l are connected to the N terminal 18c with the wires 22g, 22h, 22i, 22j, 22k, and 22l as the second conductive members. Thus, the first and second conductive members can be used to make a more reliable electrical connection. The first and second conductive members may include at least one of wires and copper clips. The copper clip may be integrated with the O terminal 18b or the N terminal 18c.

It should be noted that in the above embedment, the electrical connection between the P terminal 18a and the first conductor 31a may include at least one of bonding with solder, ultrasonic bonding, bonding by welding, bonding with wire, and bonding by sintering. This makes it possible to realize an electrical connection between the P terminal 18a and the first conductor 31a that is more suited to the user requirements and the characteristics required as the semiconductor device 11a.

In the present embodiment, the O terminal 18b includes a region arranged parallel to the N terminal 18c. Therefore, by making the direction of the current flowing through the O terminal 18b and the direction of the current flowing through the N terminal 18c opposite to each other in the regions arranged in parallel, the magnetic fluxes generated when the current flows through the terminals are canceled, and the inductance of the current path is subtracted by the mutual inductance. The inductance can thus be reduced.

In the present embodiment, the P terminal 18a includes a region arranged parallel to the O terminal 18b. Therefore, by making the direction of the current flowing through the P terminal 18a and the direction of the current flowing through the O terminal 18b opposite to each other in the regions arranged in parallel, the magnetic fluxes generated when the current flows through the terminals are canceled, and the inductance of the current path is subtracted by the mutual inductance. The inductance can thus be reduced.

In the above embodiment, at least one of the P terminal 18a and the first conductor 31a may include a region arranged parallel to the O terminal 18b. According to such a configuration, the direction of the current flowing through at least one of the P terminal 18a and the first conductor 31a and the direction of the current flowing through the O terminal 18b are made opposite in the regions arranged in parallel, whereby the magnetic fluxes generated when current flows through the terminals or the first conductor 31a and the O terminal 18b are canceled, and the inductance of the current path is subtracted by the mutual inductance. The inductance can thus be reduced.

In the present embodiment, the P terminal 18a includes a region arranged parallel to the O terminal 18b and the N terminal 18c. With this, the inductance of the path from the P terminal 18a to the N terminal 18c can also be reduced.

It should be noted that in the above embodiment, at least one of the P terminal 18a and the first conductor 31a may include a region parallel to the O terminal 18b and the N terminal 18c. With this, the inductance of the path from the P terminal 18a to the N terminal 18c can also be reduced.

In the present embodiment, a plurality of first transistor chips 21a, 21b, 21c, 21d, 21e, and 21f are provided. A plurality of second transistor chips 21g, 21h, 21i, 21j, 21k, and 21l are provided. Therefore, the plurality of first transistor chips 21a, 21b, 21c, 21d, 21e, and 21f and the plurality of second transistor chips 21g, 21h, 21i, 21j, 21k, and 21l can be used to suppress the temperature rise in each chip. Further, the number of chips can be increased in accordance with the current.

In the present embodiment, as viewed in the thickness direction of the first transistor chips 21a, 21b, 21c, 21d, 21e, and 21f, the first gate control terminal 41a is connected to the first transistor chips 21a, 21b, 21c, 21d, 21e, and 21f in its region arranged parallel to the first source sense control terminal 46a. The second gate control terminal 51a is connected to the second transistor chips 21g, 21h, 21i, 21j, 21k, and 21l in its region arranged parallel to the second source sense control terminal 56a. With this, variation in the gate loop inductance in each chip of the plurality of transistor chips connected in these regions can be suppressed because the inductance is reduced in the regions arranged in parallel.

In the present embodiment, a plurality of wires 22a, 22b, 22c, 22d, 22e, and 22f, which are the first conductive members, are provided. The wires 22a, 22b, 22c, 22d, 22e, and 22f are equivalent in length. A plurality of wires 22g, 22h, 22i, 22j, 22k, and 22l, which are the second conductive members, are provided. The wires 22g, 22h, 22i, 22j, 22k, and 22l are equivalent in length. In this manner, variation in the loop inductance in each chip can be suppressed.

In the present embodiment, the semiconductor device 11a includes the first gate control terminal 41a which is plate-shaped and connected to the gate pads of the first transistor chips 21a, 21b, 21c, 21d, 21e, and 21f. As viewed in the thickness direction of the first transistor chips 21a, 21b, 21c, 21d, 21e, and 21f, the first gate control terminal 41a has a region overlapping with the first conductor 31a with spacing therebetween in the thickness direction. Further, the semiconductor device 11a includes the second gate control terminal 51a which is plate-shaped and connected to the gate pads of the second transistor chips 21g, 21h, 21i, 21j, 21k, and 21l. As viewed in the thickness direction of the second transistor chips 21g, 21h, 21i, 21j, 21k, and 21l, the second gate control terminal 51a has a region overlapping with the second conductor 31b with spacing therebetween in the thickness direction. This makes it possible to use the overlapping regions to reduce the length of the member connecting the first gate control terminal 41a to the first conductor 31a and the length of the member connecting the second gate control terminal 51a to the second conductor 31b. Accordingly, the path length of the current path can be shortened, leading to reduced inductance.

In the present embodiment, the semiconductor device 11a includes the wires 24a, 24b, 24c, 24d, 24e, 24f, 24g, 24h, 24i, 24j, 24k, and 24l, which are the third conductive members. The first gate control terminal 41a is connected to the gate pads of the first transistor chips 21a, 21b, 21c, 21d, 21e, and 21f with the wires 24a, 24b, 24c, 24d, 24e, and 24f. Further, the second gate control terminal 51a is connected to the gate pads of the second transistor chips 21g, 21h, 21i, 21j, 21k, and 21l with the wires 24g, 24h, 24i, 24j, 24k, and 24l. In this manner, a more reliable electrical connection can be made using the third conductive members. The third conductive member may include at least one of a wire and a copper clip. The copper clip may be integrated with the gate control terminal.

In the present embodiment, the semiconductor device 11a includes the first source sense control terminal 46a which is plate-shaped and connected to the source pads of the first transistor chips 21a, 21b, 21c, 21d, 21e, and 21f. As viewed in the thickness direction of the first transistor chips 21a, 21b, 21c, 21d, 21e, and 21f, the first source sense control terminal 46a has a region overlapping with the first conductor 31a with spacing therebetween in the thickness direction. Further, the semiconductor device 11a includes the second source sense control terminal 56a which is plate-shaped and connected to the source pads of the second transistor chips 21g, 21h, 21i, 21j, 21k, and 21l. As viewed in the thickness direction of the first transistor chips 21a, 21b, 21c, 21d, 21e, and 21f, the second source sense control terminal 56a has a region overlapping with the second conductor 31b with spacing therebetween in the thickness direction. With this, the overlapping region can be used to reduce the length of the member connecting the first source sense control terminal 46a to the first conductor 31a. Further, the overlapping region can be used to reduce the length of the member connecting the second source sense control terminal 56a to the second conductor 31b. Accordingly, the path length of the current path can be shortened, leading to reduced inductance. When heat dissipation plates (heat spreaders) are used, the first and second transistor chips are mounted on the heat spreaders. This avoids entering of a wire bonding tool between the heat spreaders, so it becomes easy to increase the heat dissipation area of the heat spreaders, thereby improving heat dissipation properties.

In the present embodiment, the semiconductor device 11a includes the wires 23a, 23b, 23c, 23d, 23e, 23f, 23g, 23h, 23i, 23j, 23k, and 23l, which are the fourth conductive members. The first source sense control terminal 46a is connected to the source pads of the first transistor chips 21a, 21b, 21c, 21d, 21e, and 21f with the wires 23a, 23b, 23c, 23d, 23e, and 23f. Further, the second source sense control terminal 56a is connected to the source pads of the second transistor chips 21g, 21h, 21i, 21j, 21k, and 21l with the wires 23g, 23h, 23i, 23j, 23k, and 23l. In this manner, a more reliable electrical connection can be made using the fourth conductive members. The fourth conductive member may include at least one of a wire and a copper clip. The copper clip may be integrated with the gate control terminal.

In the present embodiment, the first gate control terminal 41a includes a region arranged parallel to the first source sense control terminal 46a. This leads to reduced inductance as it is subtracted by the mutual inductance in the regions where the current flowing through the first gate control terminal 41a and the current flowing through the first source sense control terminal 46a are in opposite directions. The second gate control terminal 51a includes a region arranged parallel to the second source sense control terminal 56a. This leads to reduced inductance as it is subtracted by the mutual inductance in the regions where the current flowing through the second gate control terminal 51a and the current flowing through the second source sense control terminal 56a are in opposite directions.

In the above semiconductor device, as viewed in the thickness direction of the first transistor chips 21a, 21b, 21c, 21d, 21e, and 21f, the first gate control terminal 41a is connected to the first transistor chips 21a, 21b, 21c, 21d, 21e, and 21f in its region arranged parallel to the first source sense control terminal 46a. With this, variation in the gate loop inductance in each chip of the plurality of transistor chips connected in this region can be suppressed because the inductance is reduced in the regions arranged in parallel. Further, as viewed in the thickness direction of the first transistor chips 21a, 21b, 21c, 21d, 21e, and 21f, the second gate control terminal 51a is connected to the second transistor chips 21g, 21h, 21i, 21j, 21k, and 21l in its region arranged parallel to the second source sense control terminal 56a. With this, variation in the gate loop inductance in each chip of the plurality of transistor chips connected in this region can be suppressed because the inductance is reduced in the regions arranged in parallel.

In the present embodiment, a plurality of wires 24a, 24b, 24c, 24d, 24e, 24f, 24g, 24h, 24i, 24j, 24k, and 24l, which are the third conductive members, are provided. The wires 24a, 24b, 24c, 24d, 24e, and 24f each have an equivalent length. The wires 24g, 24h, 24i, 24j, 24k, and 24l each have an equivalent length. This can suppress the variation of the gate loop inductance in the chips.

In the present embodiment, a plurality of wires 23a, 23b, 23c, 23d, 23e, 23f, 23g, 23h, 23i, 23j, 23k, and 23l, which are the fourth conductive members, are provided. The wires 23a, 23b, 23c, 23d, 23e, and 23f each have an equivalent length. The wires 23g, 23h, 23i, 23j, 23k, and 23l each have an equivalent length. This can suppress the variation of the gate loop inductance in the chips.

Here, the above-described semiconductor device 11a was used to conduct a simulation on inductance. The results were that the inductance between the P terminal 18a and the N terminal 18c was 2.07 nH, the inductance between the P terminal 18a and the O terminal 18b was 0.95 nH, and the inductance between the O terminal 18b and the N terminal 18c was 1.18 nH. As such, the above semiconductor device 11a is capable of reducing the inductance. Further, an analysis of the variation in inductance showed that between the P terminal 18a and the O terminal 18b, the inductance of the first transistor chip 21a was 1.94 nH and that of the first transistor chip 21f was 3.95 nH. The difference between them was 2.01 nH. Between the O terminal 18b and the N terminal 18c, the inductance of the second transistor chip 21g was 2.40 nH and that of the second transistor chip 21l was 4.25 nH. The difference between them was 1.85 nH. It can be appreciated that the differences are greatly reduced compared to the inductance differences determined solely by self-inductance. The inductance values in the analysis refer to the values at 1 MHz.

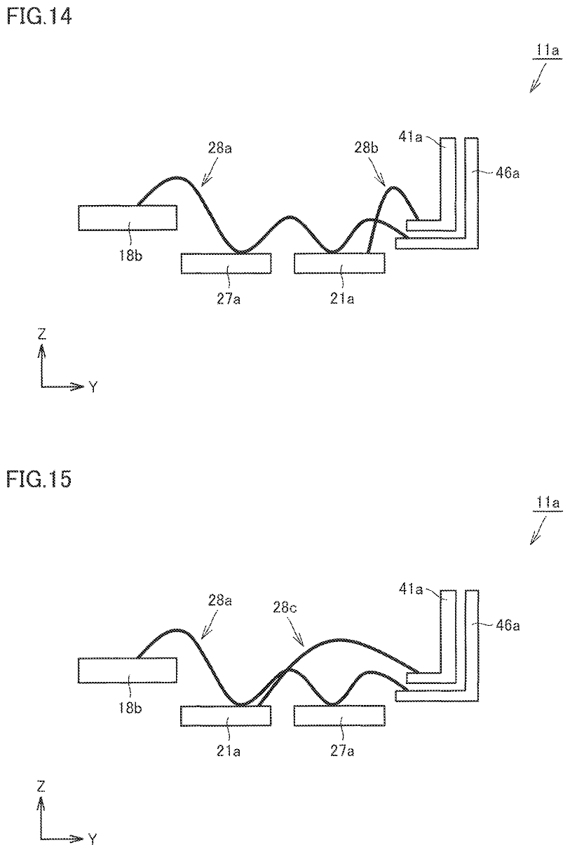

In the above embodiment, the semiconductor device may further include a diode chip electrically connected in parallel with at least one of the first transistor chip and the second transistor chip. FIG. 14 is a schematic cross-sectional view of a portion of the semiconductor device including the diode chip. Referring to FIG. 14, the semiconductor device 11a includes a Schottky barrier diode as the diode chip 27a. The diode chip 27a is arranged on the O terminal 18b side with respect to the first transistor chip 21a. A wire 28a electrically connects the first source sense control terminal 46a, a source pad of the first transistor chip 21a, a cathode pad of the diode chip 27a, and the O terminal 18b. A wire 28b electrically connects the first gate control terminal 41a to a gate pad of the first transistor chip 21a.

The above allows a return current to flow through the diode chip 27a, thereby preventing an overvoltage from being applied to the first transistor chip 21a. Thus, reliability can be improved. In addition, the wire 28b as the connecting member connecting the gate pad of the first transistor chip 21a to the first gate control terminal 41a can be reduced in length. Thus, the wiring length can be shortened, leading to reduced inductance.

Further, in the above semiconductor device 11a, the first transistor chip 21a and the diode chip 27a may be electrically connected in parallel. The first transistor chip 21a may be arranged on the O terminal 18b side with respect to the diode chip 27a. FIG. 15 is a schematic cross-sectional view of a portion of the semiconductor device including the diode chip. Referring to FIG. 15, the first transistor chip 21a and the diode chip 27a are electrically connected in parallel. A wire 28c electrically connects the first gate control terminal 41a to the gate pad of the first transistor chip 21a. The first transistor chip 21a is arranged on the O terminal 18b side with respect to the diode chip 27a. This can reduce the length of the wire 28a, which is the connecting member connecting the source pad of the first transistor chip 21a to the O terminal 18b. Thus, the wiring length can be shortened, leading to reduced inductance.

In the above semiconductor device 11a, the second transistor chip 21g and the diode chip 27a may be electrically connected in parallel. The diode chip 27a may be arranged on the N terminal 18c side with respect to the second transistor chip 21g. This allows a return current to flow through the diode chip 27a, thereby preventing an overvoltage from being applied to the second transistor chip 21g. Thus, reliability can be improved. In addition, the wire as the connecting member connecting the gate pad of the second transistor chip 21g to the second gate control terminal 51a can be reduced in length. Thus, the wiring length can be shortened, leading to reduced inductance.

In the above semiconductor device 11a, the second transistor chip 21g and the diode chip 27a may be electrically connected in parallel. The second transistor chip 21g may be arranged on the N terminal 18c side with respect to the diode chip 27a. This can reduce the length of the wire as the connecting member connecting the source pad of the second transistor chip 21g to the N terminal 18c. Thus, the wiring length can be shortened, leading to reduced inductance.

It should be noted that in the above semiconductor device 11a, for the first and second circuit boards 16a and 16b provided in the circuit substrate 14a, the first conductor 31a may include the first circuit board 16a. The second conductor 31b may include the second circuit board 16b. With this, in the case where the heat dissipation plates 33a, 33b, 33c, 33d, 33e, and 33f are used, thicker heat dissipation plates 33a, 33b, 33c, 33d, 33e, and 33f can be arranged, which can further improve the heat dissipation properties.

### Embodiment 2

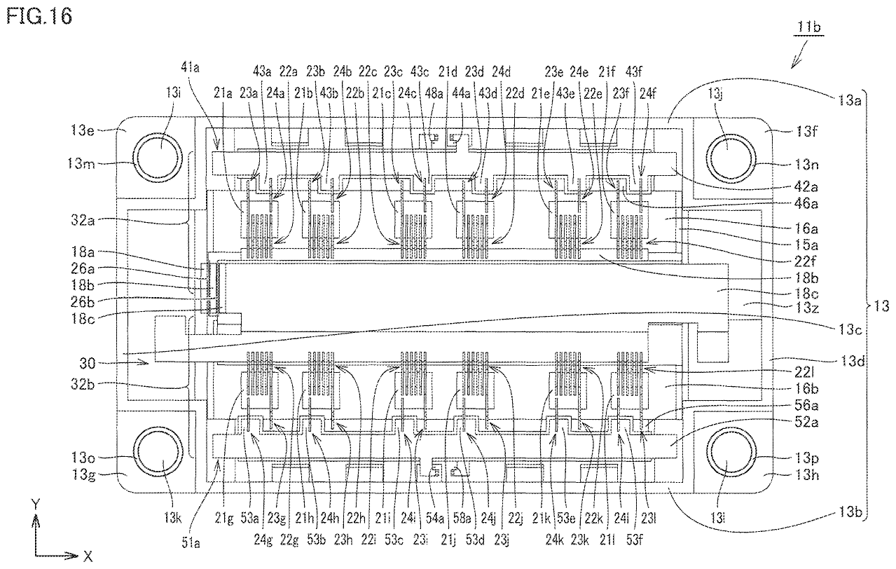

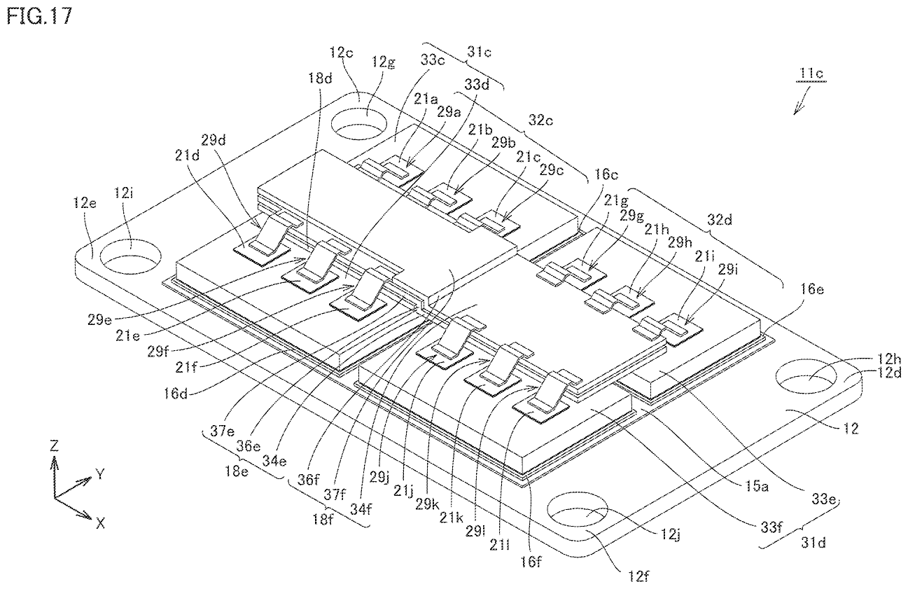

Another embodiment, Embodiment 2, will now be described. FIG. 16 is a schematic plan view of a semiconductor device in Embodiment 2. The semiconductor device in Embodiment 2 differs from that in Embodiment 1 in the configuration of the first and second conductors.

Referring to FIG. 16, the semiconductor device 11b in Embodiment 2 does not include the heat dissipation plates 33a, 33b, 33c, 33d, 33e, and 33f. The device includes a first circuit board 16a as the first conductor 31a and a second circuit board 16b as the second conductor 31b. In other words, the first transistor chips 21a, 21b, 21c, 21d, 21e, and 21f are directly bonded to the first circuit board 16a, and the second transistor chips 21g, 21h, 21i, 21j, 21k, and 21l are directly bonded to the second circuit board 16b. In this case as well, no wires are directly connected to the first and second circuit boards 16a and 16b. The inductance can also be reduced with this configuration.

### Embodiment 3

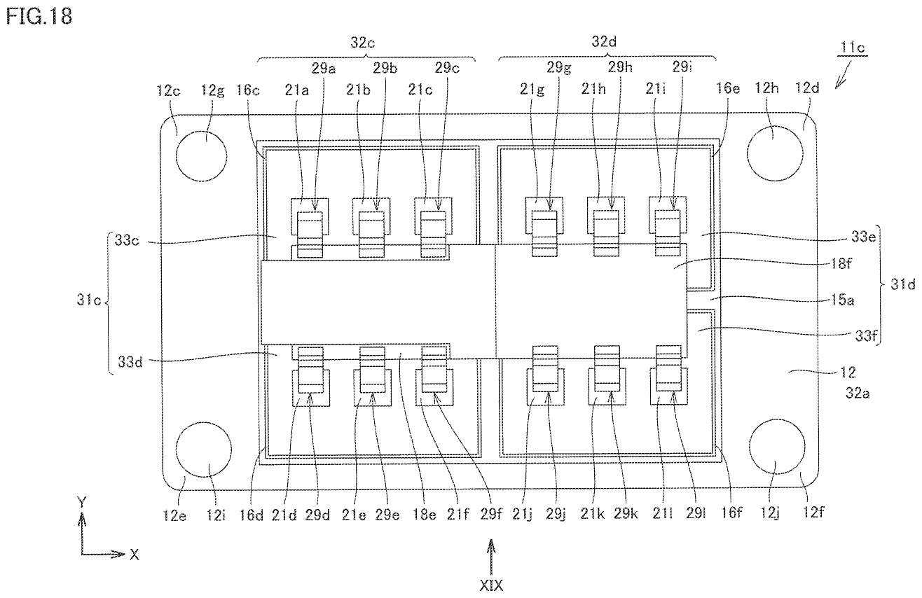

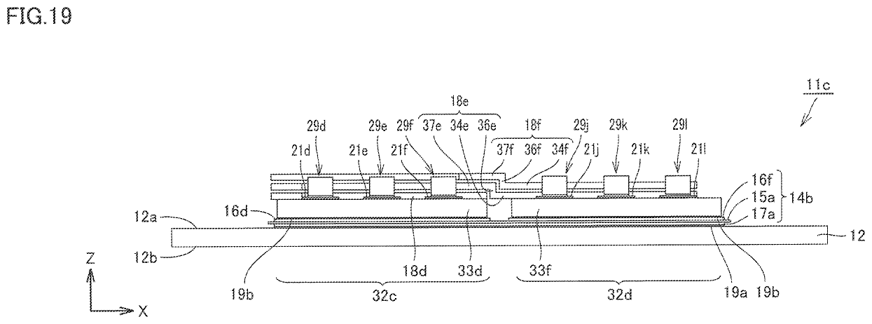

Yet another embodiment, Embodiment 3, will now be described. FIG. 17 is a schematic perspective view of a semiconductor device in Embodiment 3, with illustrations of the sealing material, frame, and the like omitted. FIG. 18 is a schematic plan view of the semiconductor device shown in FIG. 17. FIG. 19 is a schematic side view of the semiconductor device shown in FIG. 18, as viewed in the direction indicated by the arrow XIX in FIG. 18. The semiconductor device in Embodiment 3 differs from that in Embodiment 1 in the configuration of the first and second conductors.

Referring to FIGS. 17, 18, and 19, a circuit substrate 14b included in the semiconductor device 11c of Embodiment 3 includes a first circuit board 16c, a second circuit board 16d, a first circuit board 16e, and a second circuit board 16f which are disposed on an insulating plate 15a. The first circuit board 16c and the second circuit board 16d are arranged spaced apart in the Y direction. The first circuit board 16e and the second circuit board 16f are arranged spaced apart in the Y direction. The first circuit board 16c and the first circuit board 16e are arranged spaced apart in the X direction. The second circuit board 16d and the second circuit board 16f are arranged spaced apart in the X direction.

The semiconductor device 11c includes four heat dissipation plates 33g, 33h, 33i, and 33j. The heat dissipation plates 33g, 33h, 33i, and 33j are each arranged spaced apart in the X and Y directions. Specifically, the heat dissipation plates 33g and 33h are arranged to have the same position in the X direction and different positions in the Y direction. The heat dissipation plates 33i and 33j are arranged to have the same position in the X direction and different positions in the Y direction. The heat dissipation plate 33g is arranged on the first circuit board 16c. The heat dissipation plate 33g is bonded to the first circuit board 16c. The heat dissipation plate 33h is arranged on the second circuit board 16d. The heat dissipation plate 33h is bonded to the second circuit board 16d. The heat dissipation plate 33i is arranged on the first circuit board 16e. The heat dissipation plate 33i is bonded to the first circuit board 16e. The heat dissipation plate 33j is arranged on the second circuit board 16f. The heat dissipation plate 33j is bonded to the second circuit board 16f. The heat dissipation plates 33g and 33h constitute a first conductor 31c. The heat dissipation plates 33i and 33j constitute a second conductor 31d.

In the present embodiment, first transistor chips 21a, 21b, and 21c are arranged on the heat dissipation plate 33g. The first transistor chips 21a, 21b, and 21c are bonded to the heat dissipation plate 33g. First transistor chips 21d, 21e, and 21f are arranged on the heat dissipation plate 33h. The first transistor chips 21d, 21e, and 21f are bonded to the heat dissipation plate 33h. Second transistor chips 21g, 21h, and 21i are arranged on the heat dissipation plate 33i. The second transistor chips 21g, 21h, and 21i are bonded to the heat dissipation plate 33h. Second transistor chips 21j, 21k, and 21l are arranged on the heat dissipation plate 33j. The second transistor chips 21j, 21k, and 21l are bonded to the heat dissipation plate 33h.

A P terminal 18d is bonded to the heat dissipation plates 33g and 33h. In the present embodiment, the P terminal 18d is bonded across the two heat dissipation plates 33g and 33h. An O terminal 18e includes a first flat region 34e, a third flat region 36e, and a fourth flat region 37e. The O terminal 18e is bonded to the heat dissipation plates 33i and 33j. That is, the O terminal 18e is bonded across the two heat dissipation plates 33i and 33j. An N terminal 18f includes a first flat region 34f, a third flat region 36f, and a fourth flat region 37f. The fourth flat region 37f of the N terminal 18f has a partially cut-out shape. Specifically, the fourth flat region 37f is configured to have a portion in which the length between the two ends in the Y direction is shortened, causing a portion of the fourth flat region 37e of the O terminal 18e to be exposed as viewed in the thickness direction of the first transistor chips 21a, 21b, 21c, 21d, 21e, and 21f. Attached to this exposed region are copper clips 29a, 29b, 29c, 29d, 29e, and 29f, which are described below.

The first transistor chips 21a, 21b, 21c, 21d, 21e, and 21f are electrically connected to the O terminal 18e with the copper clips 29a, 29b, 29c, 29d, 29e, and 29f as the first conductive members. The second transistor chips 21g, 21h, 21i, 21j, 21k, and 21l are electrically connected to the N terminal 18f with copper clips 29g, 29h, 29i, 29j, 29k, and 291 as the second conductive members. The current path including the first transistor chips 21a, 21b, 21c, 21d, 21e, and 21f constitutes an upper arm 32c, which is the first arm. The current path including the second transistor chips 21g, 21h, 21i, 21j, 21k, and 21l constitutes a lower arm 32d, which is the second arm. In this configuration, the copper clips are capable of easily securing a large cross-sectional area, allowing more current to flow. Wiring resistance can also be reduced.

### Embodiment 4

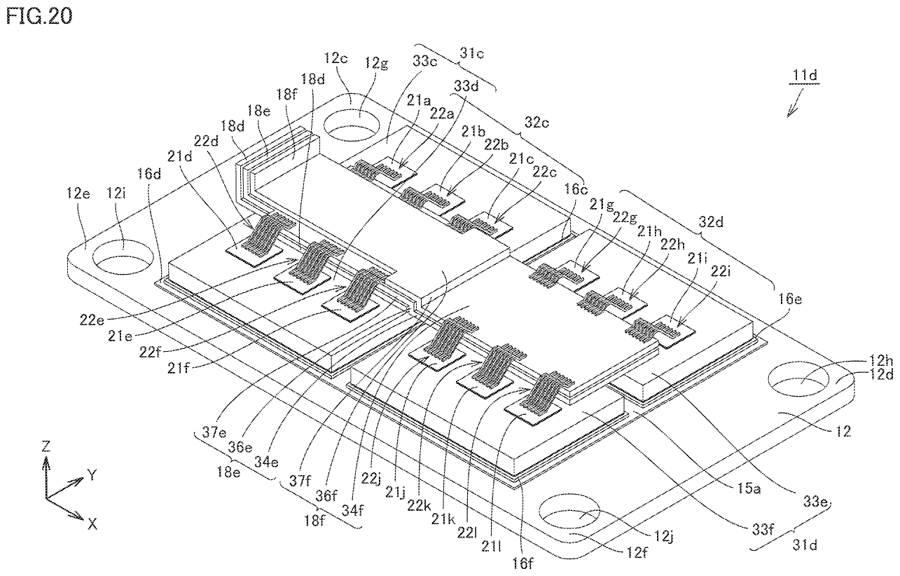

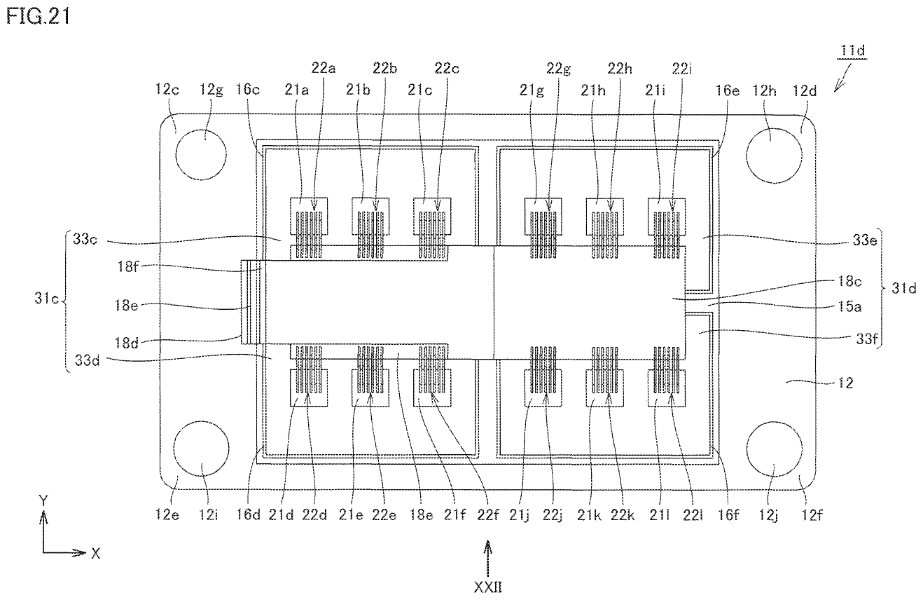

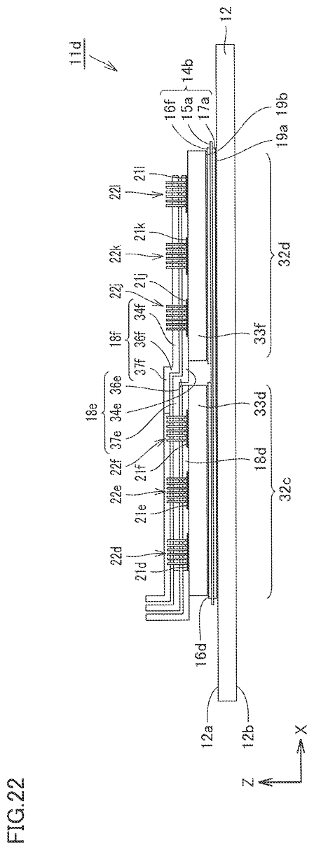

Yet another embodiment, Embodiment 4, will now be described. FIG. 20 is a schematic perspective view of a semiconductor device in Embodiment 4, with illustrations of the sealing material, frame, and the like omitted. FIG. 21 is a schematic plan view of the semiconductor device shown in FIG. 20. FIG. 22 is a schematic side view of the semiconductor device shown in FIG. 21, as viewed in the direction indicated by the arrow XXII in FIG. 21. The semiconductor device in Embodiment 4 differs from that in Embodiment 3 in that wires are used in place of the copper clips.

Referring to FIGS. 20, 21, and 22, the semiconductor device 11d of Embodiment 4, unlike the semiconductor device 11c of Embodiment 3, includes wires 22a, 22b, 22c, 22d, 22e, and 22f as the first conductive members which electrically connect the first transistor chips 21a, 21b, 21c, 21d, 21e, and 21f to the O terminal 18e. The semiconductor device 11d also includes wires 22g, 22h, 22i, 22j, 22k, and 22l as the second conductive members which electrically connect the second transistor chips 21g, 21h, 21i, 21j, 21k, and 21l to the N terminal 18f. According to this configuration, the stress applied to the chips can be reduced compared to the case of copper clips, leading to improved reliability.

### OTHER EMBODIMENTS

While wires or copper clips are used as the conductive members in the above embodiments, not limited thereto, ribbon wires or thick aluminum wires, for example, may be used as the conductive members.

Further, while the N terminal, the first gate control terminal, the second gate control terminal, the first source sense control terminal, and the second source sense control terminal are arranged in the frame in the present embodiment, the configuration is not limited thereto. The N terminal, the first gate control terminal, the second gate control terminal, the first source sense control terminal, and the second source sense control terminal may be insert-molded into the frame to form a single unit.

It should be noted that while the number of each of the first and second transistor chips is plural in the above embodiments, not limited thereto, it may be one each. Further, the plurality of first transistor chips and the plurality of second transistor chips need not be arranged in a row in the X direction or the Y direction.

It should be understood that the embodiments disclosed herein are illustrative and non-restrictive in every respect. The scope of the present invention is defined by the terms of the claims, rather than the description above, and is intended to include any modifications within the scope and meaning equivalent to the terms of the claims.

### REFERENCE SIGNS LIST

11a, 11b, 11c, 11d: semiconductor device; 12: base plate; 12a: first surface; 12b: second surface; 12c, 12d, 12e, 12f, 13e, 13f, 13g, 13h: corner region; 12g, 12h, 12i, 12j, 13i, 13j, 13k, 13l, 13v, 13w, 13x, 13y: through hole; 13: frame; 13a: first wall portion; 13b: second wall portion; 13c: third wall portion; 13d: fourth wall portion; 13m, 13n, 13o, 13p: annular member; 13q: first inner wall surface; 13r: second inner wall surface; 13s: third inner wall surface; 13t: fourth inner wall surface; 13u, 13z: rib; 14a, 14b: circuit substrate; 15a: insulating plate; 16a, 16c, 16e: first circuit board; 16b, 16d, 16f: second circuit board; 17a: metal plate; 18a, 18d: P terminal; 18b, 18e: O terminal; 18c, 18f: N terminal; 19a: first bonding material; 19b: second bonding material; 20: case; 20a: sealing material; 21a, 21b, 21c, 21d, 21e, 21f: first transistor chip; 21g, 21h, 21i, 21j, 21k, 21l: second transistor chip; 22a, 22b, 22c, 22d, 22e, 22f, 22g, 22h, 22i, 22j, 22k, 22l, 23a, 23b, 23c, 23d, 23e, 23f, 23g, 23h, 23i, 23j, 23k, 23l, 24a, 24b, 24c, 24d, 24e, 24f, 24g, 24h, 24i, 24j, 24k, 24l, 28a, 28b, 28c: wire; 26a, 26b, 26c: insulating member; 27a: diode chip; 29a, 29b, 29c, 29d, 29e, 29f, 29g, 29h, 29i, 29j, 29k, 291: copper clip; 30: space; 31a, 31c: first conductor; 31b, 31d: second conductor; 32a, 32c: upper arm; 32b, 32d: lower arm; 33a, 33b, 33c, 33d, 33e, 33f, 33g, 33h, 33i, 33j: heat dissipation plate; 34a, 34b, 34c, 42a, 47a, 52a, 57a: first flat region; 35a, 35b, 35c: second flat region; 36b, 36c: third flat region; 37b, 37c: fourth flat region; 41a: first gate control terminal (gate control terminal); 43a, 43b, 43c, 43d, 43e, 43f, 53a, 53b, 53c, 53d, 53e, 53f: protrusion; 44a, 48a, 54a, 58a: pin; 46a: first source sense control terminal (source sense control terminal); 51a: second gate control terminal (gate control terminal); 56a: second source sense control terminal (source sense control terminal); and D₁, D₂, D₃, D₄: arrow.

1. A semiconductor device comprising:
a first conductor;
a second conductor;
a first transistor chip mounted on the first conductor;
a second transistor chip mounted on the second conductor;
a plate-shaped P terminal;
a plate-shaped O terminal; and
a plate-shaped N terminal;
the first transistor chip having a source pad electrically connected to the O terminal,
the second transistor chip having a source pad electrically connected to the N terminal,
the first transistor chip having a drain pad electrically connected to the first conductor,
the second transistor chip having a drain pad electrically connected to the second conductor,
the P terminal being electrically connected to the first conductor,
the O terminal being bonded to the second conductor,
as viewed in a thickness direction of the first transistor chip, the O terminal including a region overlapping with the first conductor with spacing therebetween in the thickness direction,
the N terminal including a region overlapping with the second conductor with spacing therebetween in the thickness direction.

2. The semiconductor device according to claim 1, wherein the bonding between the O terminal and the second conductor includes at least one of ultrasonic bonding and bonding by welding.

3. A semiconductor device comprising:
a first conductor;
a second conductor;
a first transistor chip mounted on the first conductor;
a second transistor chip mounted on the second conductor;
a plate-shaped P terminal;
a plate-shaped O terminal; and
a plate-shaped N terminal;
the first transistor chip having a source pad electrically connected to the O terminal,
the second transistor chip having a source pad electrically connected to the N terminal,
the first transistor chip having a drain pad electrically connected to the first conductor,
the second transistor chip having a drain pad electrically connected to the second conductor,
the P terminal being electrically connected to the first conductor,
the O terminal being bonded to the second conductor with a bonding material having electrical conductivity,
as viewed in a thickness direction of the first transistor chip, the O terminal including a region overlapping with the first conductor with spacing therebetween in the thickness direction,
the N terminal including a region overlapping with the second conductor with spacing therebetween in the thickness direction.

4. The semiconductor device according to claim 3, wherein the bonding between the O terminal and the second conductor includes at least one of bonding with solder, bonding with wire, and bonding with a sintering material.

5. The semiconductor device according to claim 1, wherein at least one of the first conductor and the second conductor includes a heat dissipation plate.

6. The semiconductor device according to claim 1, further comprising a circuit substrate including a first circuit board and a second circuit board, wherein
the first conductor includes the first circuit board, and
the second conductor includes the second circuit board.

7. The semiconductor device according to claim 1, further comprising a first conductive member and a second conductive member, wherein
the source pad of the first transistor chip is connected to the O terminal with the first conductive member, and
the source pad of the second transistor chip is connected to the N terminal with the second conductive member.

8. The semiconductor device according to claim 1, wherein the electrical connection between the P terminal and the first conductor includes at least one of bonding with solder, ultrasonic bonding, bonding by welding, bonding with wire, and bonding by sintering.

9. The semiconductor device according to claim 1, wherein the O terminal includes a region arranged parallel to the N terminal.

10. The semiconductor device according to claim 1, wherein at least one of the P terminal and the first conductor includes a region arranged parallel to the O terminal.

11. The semiconductor device according to claim 1, wherein at least one of the P terminal and the first conductor includes a region arranged parallel to the O terminal and the N terminal.

12. The semiconductor device according to claim 1, wherein the second conductor includes a region arranged parallel to each of the P terminal, the O terminal, and the N terminal.

13. The semiconductor device according to claim 1, further comprising a diode chip electrically connected in parallel with at least one of the first transistor chip and the second transistor chip.

14-15. (canceled)

16. The semiconductor device according to claim 1, comprising:
a plurality of said first transistor chips; and
a plurality of said second transistor chips.

17. The semiconductor device according to claim 1, wherein
as viewed in the thickness direction of the first transistor chip, the O terminal is connected to the first transistor chip in a region of the O terminal arranged parallel to the P terminal, and
the N terminal is connected to the second transistor chip in a region of the N terminal arranged parallel to the O terminal.

18. The semiconductor device according to claim 7, comprising:
a plurality of said first conductive members,
the first conductive members each having an equivalent length; and
a plurality of said second conductive members,
the second conductive members each having an equivalent length.

19. The semiconductor device according to claim 1, further comprising a plate-shaped gate control terminal connected to a gate pad of the first transistor chip or a gate pad of the second transistor chip, wherein
as viewed in the thickness direction of the first transistor chip, the gate control terminal has a region overlapping with the first conductor or the second conductor with spacing therebetween in the thickness direction.

20. The semiconductor device according to claim 19, further comprising a third conductive member, wherein
the gate control terminal is electrically connected to the gate pad of the first transistor chip or the gate pad of the second transistor chip with the third conductive member.

21. The semiconductor device according to claim 1, further comprising a plate-shaped source sense control terminal connected to the source pad of the first transistor chip or the source pad of the second transistor chip, wherein
as viewed in the thickness direction of the first transistor chip, the source sense control terminal has a region overlapping with the first conductor or the second conductor.

22. The semiconductor device according to claim 21, further comprising a fourth conductive member, wherein
the source sense control terminal is connected to the source pad of the first transistor chip or the source pad of the second transistor chip with the fourth conductive member.

23-24. (canceled)
